(19) United States
(12) Patent Application Publication
(10) Pub. No.: US 2025/0058353 A1
(43) Pub. Date: Feb. 20, 2025

(54) SEMICONDUCTOR ULTRASONIC TRANSDUCER DEVICE AND METHODS OF FORMATION

(71) Applicant: Taiwan Semiconductor Manufacturing Company, Ltd., Hsinchu (TW)

(72) Inventors: Chia-Ming HUNG, Zhubei City (TW); Wen-Chuan TAI, Hsinchu City (TW); Chun-Heng CHEN, Hsinchu City (TW); Shao-Da WANG, New Taipei City (TW); Hsiang-Fu CHEN, Zhubei City (TW)

(21) Appl. No.: 18/451,057

(22) Filed: Aug. 16, 2023

(51) Int. Cl. B06B 1/02; B81B 3/00; B81B 7/02

(52) U.S. Cl. CPC B06B 1/0292; B81B 3/0021; B81B 7/02; B81B 2203/0127; B81B 2207/07

(57) ABSTRACT

A micro-electromechanical-system (MEMS) device may include a capacitive micromachined ultrasonic transducer (CMUT) that includes an actuation membrane and a sensing dielectric layer that are spaced apart by a cavity. The sensing dielectric layer may be formed such that the thickness of the sensing dielectric layer may extend the operational of the CMUT while enabling the CMUT to accommodate a sufficiently high direct current voltage bias for collapsed mode operation. In this way, the thickness of the sensing dielectric layer enables the CMUT to operate in the collapsed mode, which enables the CMUT to achieve greater sound pressure output relative to other operational modes and enables the frequency response of the CMUT to be adjustable, thereby enabling the frequency response to be optimized for specific use cases and applications.

### BACKGROUND

Integrated circuits may be fabricated on a semiconductor wafer. Semiconductor wafers can be stacked or bonded on top of each other to form what is referred to as a three-dimensional integrated circuit. Some semiconductor wafers include micro-electromechanical-system (MEMS) devices, which involve the process of forming micro-structures with dimensions in the micrometer scale (one millionth of a meter). Typically, MEMS devices are built on silicon wafers and realized in thin films of materials. MEMS applications include inertial sensors applications (e.g., motion sensors, accelerometers, gyroscopes), pressure sensors, microfluidic devices (e.g., valves, pumps), movable mirrors, and imaging devices (e.g., micromachined ultrasonic transducers), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor device described herein.

FIGS. 3A and 3B are diagrams of example implementations of operating modes of a capacitive micromachined ultrasonic transducer (CMUT) of a semiconductor device described herein.

FIGS. 4A-4V are diagrams of an example implementation of forming the semiconductor device (or a portion thereof) described herein.

FIG. 5 is a diagram of an example semiconductor device described herein.

FIGS. 6A-6E are diagrams of an example implementation of forming the semiconductor device (or a portion thereof) described herein.

FIG. 7 is a diagram of an example semiconductor device described herein.

FIGS. 8A-8H are diagrams of an example implementation of forming the semiconductor device (or a portion thereof) described herein.

FIG. 9 is a diagram of example components of a device described herein.

FIG. 10 is a flowchart of an example process associated with forming a semiconductor device described herein.

FIG. 11 is a flowchart of an example process associated with forming a semiconductor device described herein.

FIG. 12 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Micromachined ultrasonic transducers (MUTs), such as piezoelectric MUTs (PMUTs) and capacitive MUTs (CMUTs), may be included in a micro-electromechanical-system (MEMS) device such as a fingerprint sensor, a high-intensity focused ultrasound sensor, a medical ultrasound imaging sensor, and/or another contact-type sensor. A CMUT, for example, may include an actuation membrane, a sensing dielectric layer under the actuation membrane, and an air gap separating the actuation membrane and the sensing dielectric layer to enable the membrane to be displaced. A voltage may be applied to the actuation membrane to cause the actuation membrane to be displaced, which results in the CMUT emitting an ultrasonic signal (e.g., in the case where the CMUT is configured as an ultrasonic transmitter). Additionally and/or alternatively, the CMUT may be configured as an ultrasonic receiver such that an ultrasonic signal may be received by the actuation membrane, which causes the actuation membrane to be displaced. The displacement of the actuation membrane may cause the CMUT to generate a signal (e.g., a voltage signal, a current signal) based on the received ultrasonic signal, thereby enabling the CMUT to sense ultrasonic reflections (e.g., from a fingerprint).

In some cases, a CMUT may be configured to operate in a particular operational mode, such as a free-standing mode or a collapsed mode. In a free-standing mode, the actuation membrane of the CMUT is operated using a direct current (DC) voltage bias (V_{dc-bias}) that is less than a collapse voltage (V_{collapse}) of the actuation membrane. This results in the actuation membrane being able to vibrate freely, which results in fewer reliability concerns relative to the collapsed mode. However, the sound pressure that may be achievable by the CMUT in the free-standing mode is less than the sound pressure that may be achievable by the CMUT in the collapsed mode. In the collapsed mode, the actuation membrane of the CMUT is operated using a V_{dc-bias} that is greater than the V_{collapse} of the actuation membrane, resulting in the actuation membrane being stretched against contact pedestals of the underlying sensing dielectric layer. While the collapsed mode may provide greater sound pressure output for the CMUT and may enable the frequency response of the actuation membrane to be adjustable, the stretching of the actuation membrane against the pedestals can cause a dielectric coating on the underside of the actuation membrane to become damaged and to wear out. This may result in premature failure of the CMUT and/or may otherwise reduce the operational life of the CMUT, among other examples.

In some implementations described herein, a MEMS device may include a CMUT that includes an actuation membrane and a sensing dielectric layer that are spaced apart by a cavity (e.g., an airgap). The sensing dielectric layer may be formed such that the thickness of the sensing dielectric layer may extend the operational life of the CMUT while enabling the CMUT to accommodate a sufficiently high V_{dc-bias} for collapsed mode operation. For example, the thickness of the sensing dielectric layer may be greater than a thickness of the dielectric coating on the underside of the actuation membrane. In this way, the thickness of the sensing dielectric layer enables the CMUT to operate in the collapsed mode, which enables the CMUT to achieve greater sound pressure output relative to other operational modes and enables the frequency response of the CMUT to be adjustable, thereby enabling the frequency response to be optimized for specific use cases and applications. Moreover, the thickness of the sensing dielectric layer may enable the CMUT to operate at a sustained high breakdown voltage over a longer period of time (e.g., relative to CMUTs that include a thinner sensing dielectric layer), which reduces the likelihood of premature wear out and extends the operational life of the CMUT.

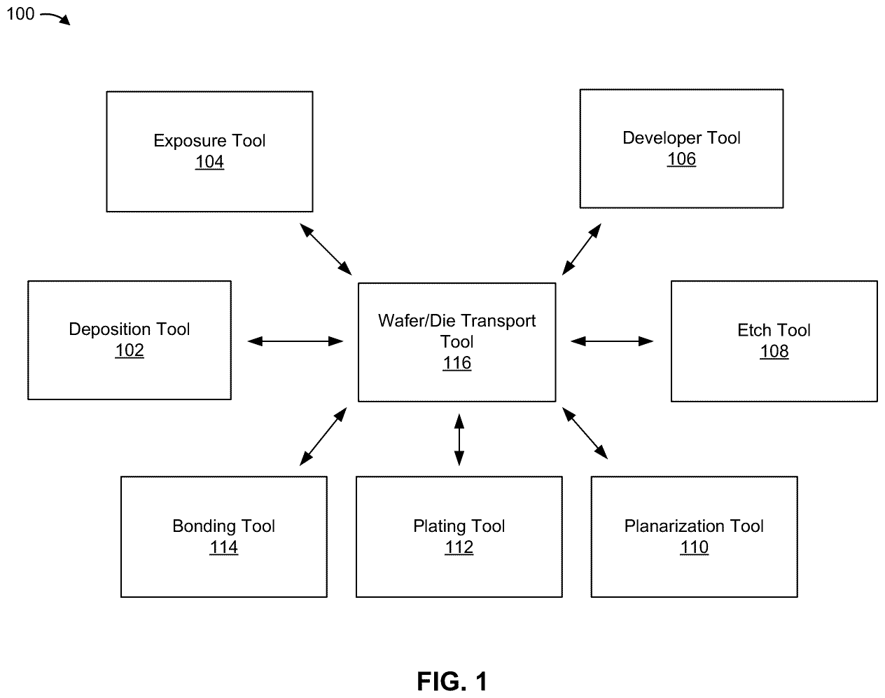

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, a bonding tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of deposition tools 102 and/or a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool. In some implementations, the example environment 100 includes a plurality of exposure tools 104 and/or a plurality of types of exposure tools 104.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer. In some implementations, the example environment 100 includes a plurality of developer tools 106 and/or a plurality of types of developer tools 106.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions. In some implementations, the example environment 100 includes a plurality of etch tool 108 and/or a plurality of types of etch tools 108.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar. In some implementations, the example environment 100 includes a plurality of planarization tools 110 and/or a plurality of types of planarization tools 110.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials. In some implementations, the example environment 100 includes a plurality of plating tools 112 and/or a plurality of types of plating tools 112.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116 and/or a plurality of types of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of a deposition tool 102 without breaking or removing a vacuum (or an at least partial vacuum) between the processing chambers and/or between processing operations in the deposition tool 102, as described herein.

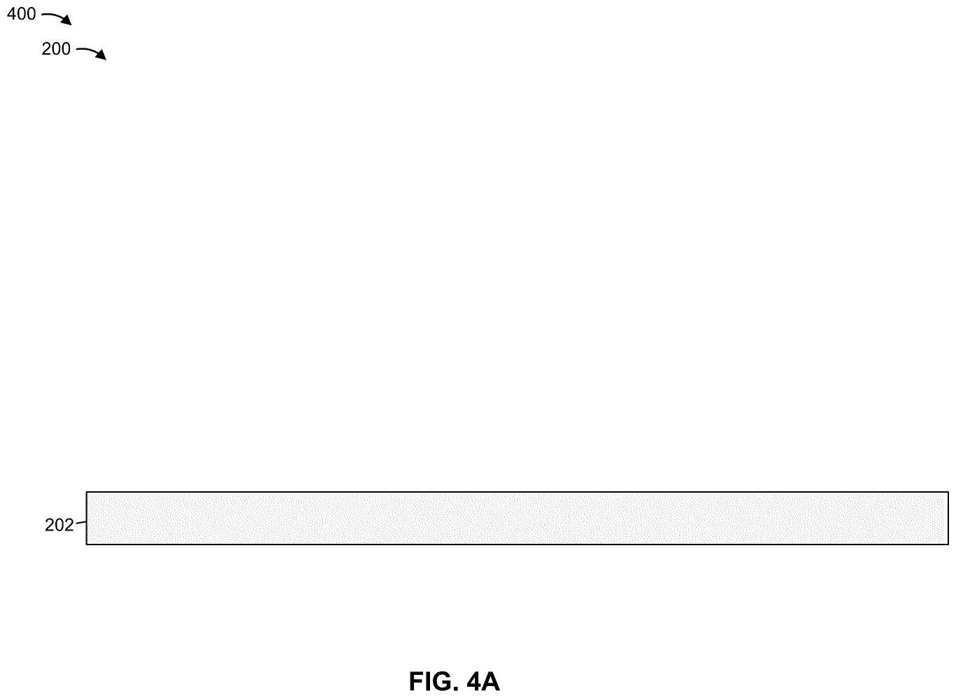

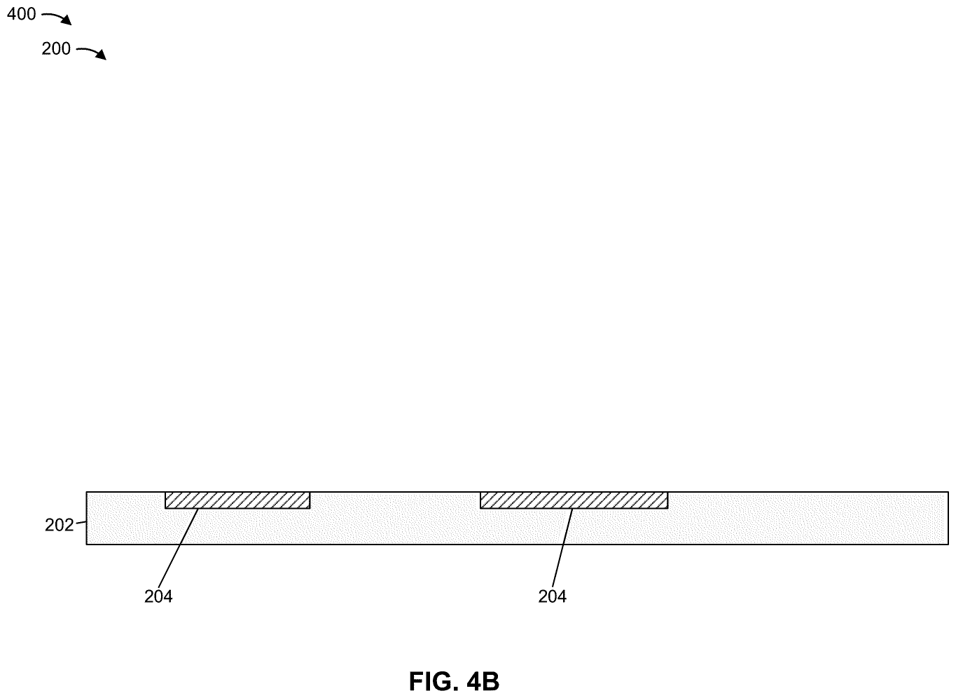

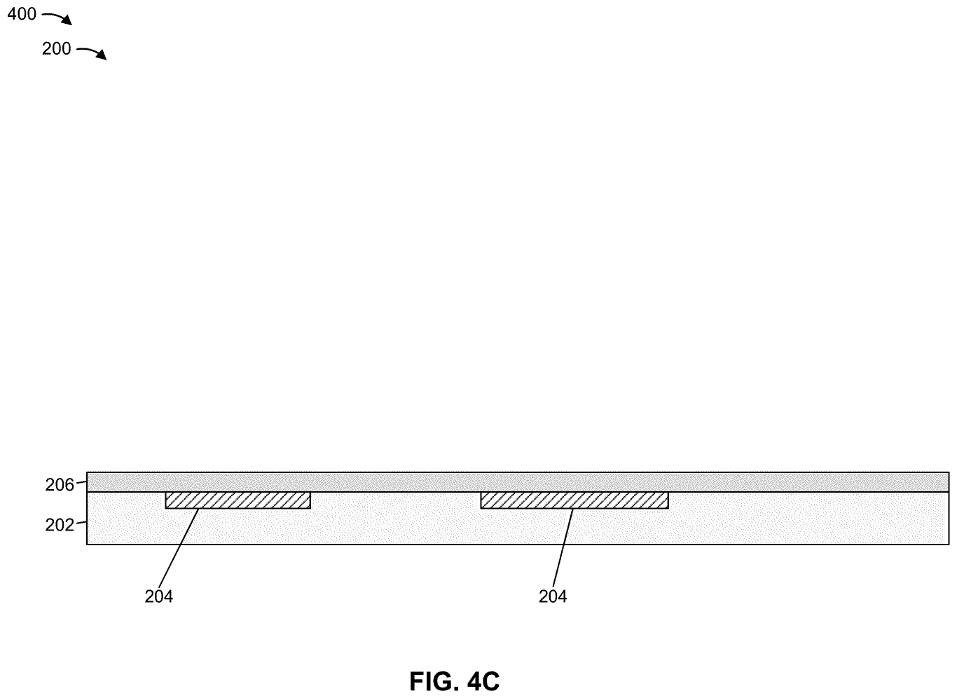

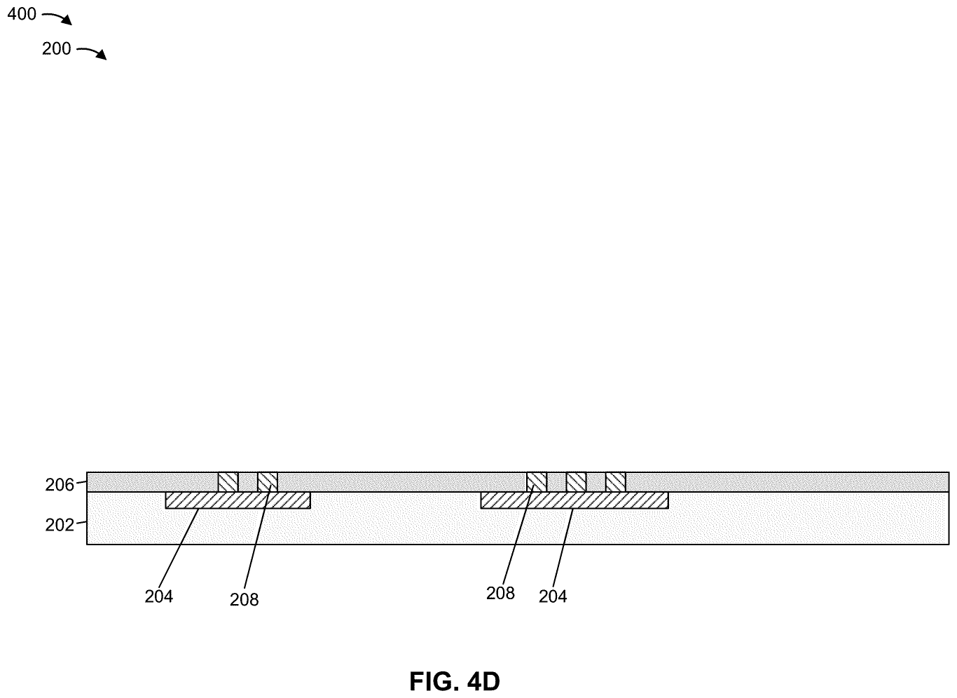

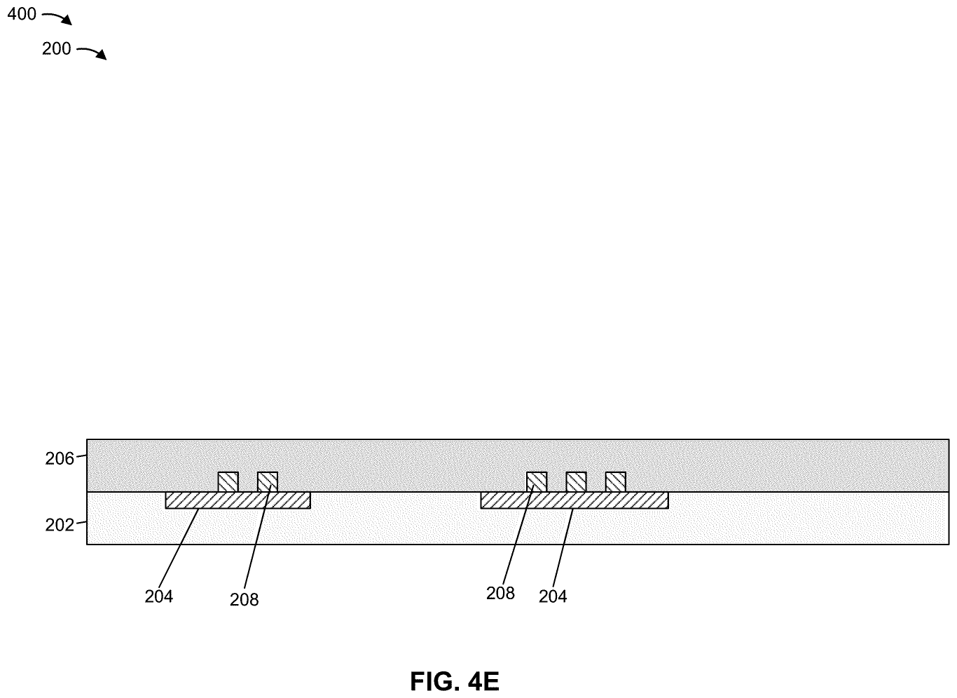

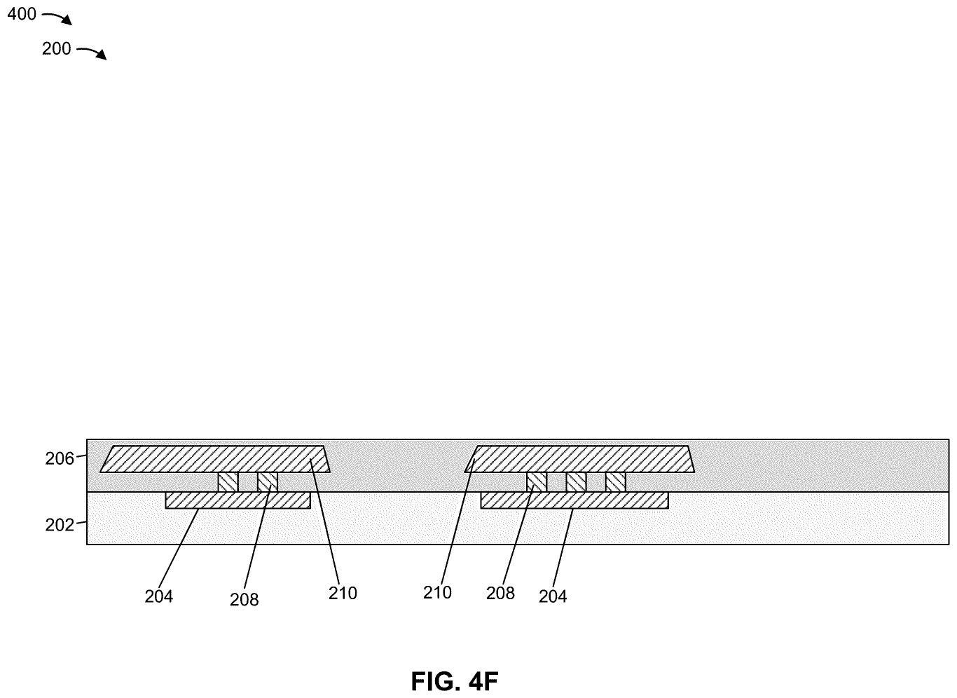

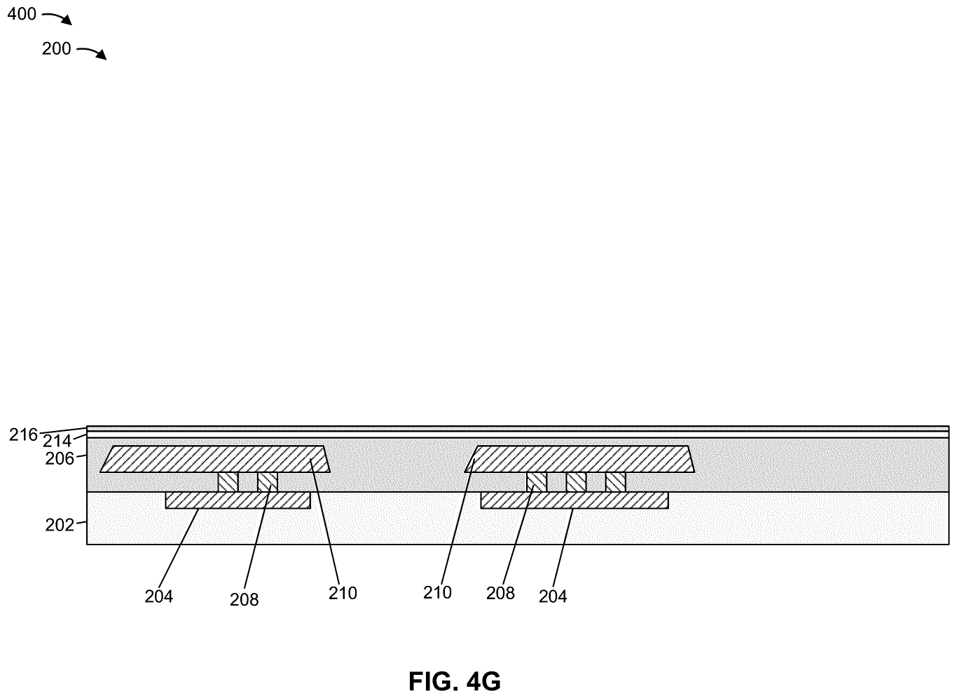

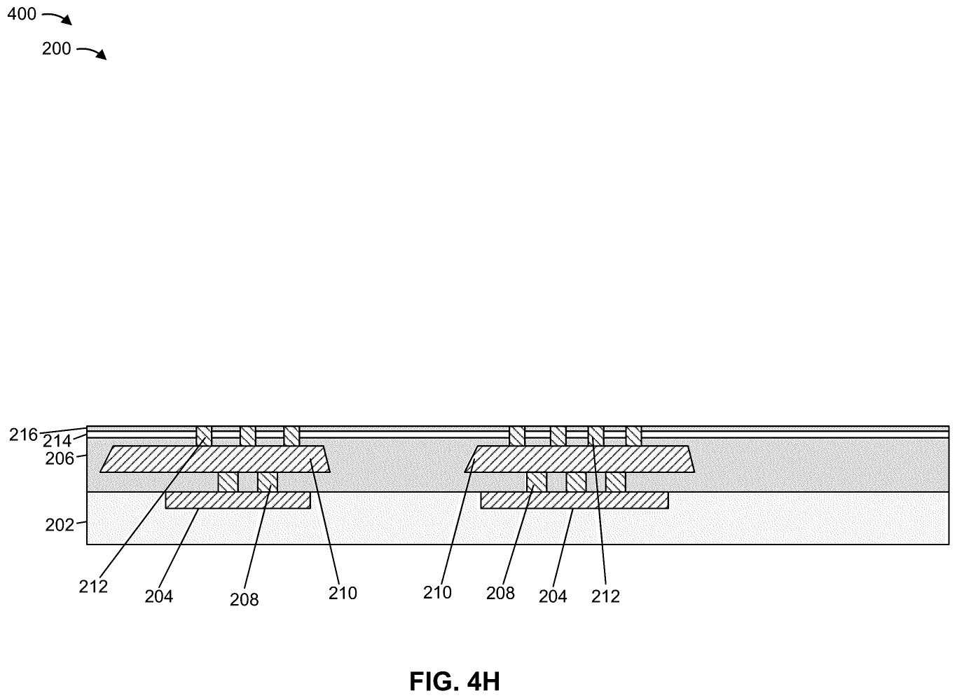

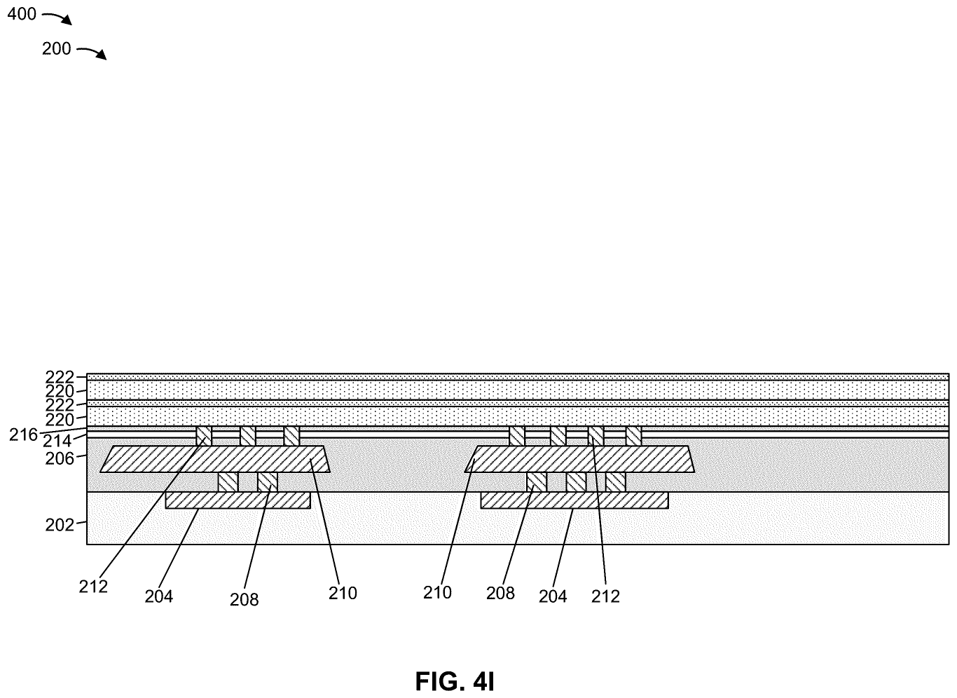

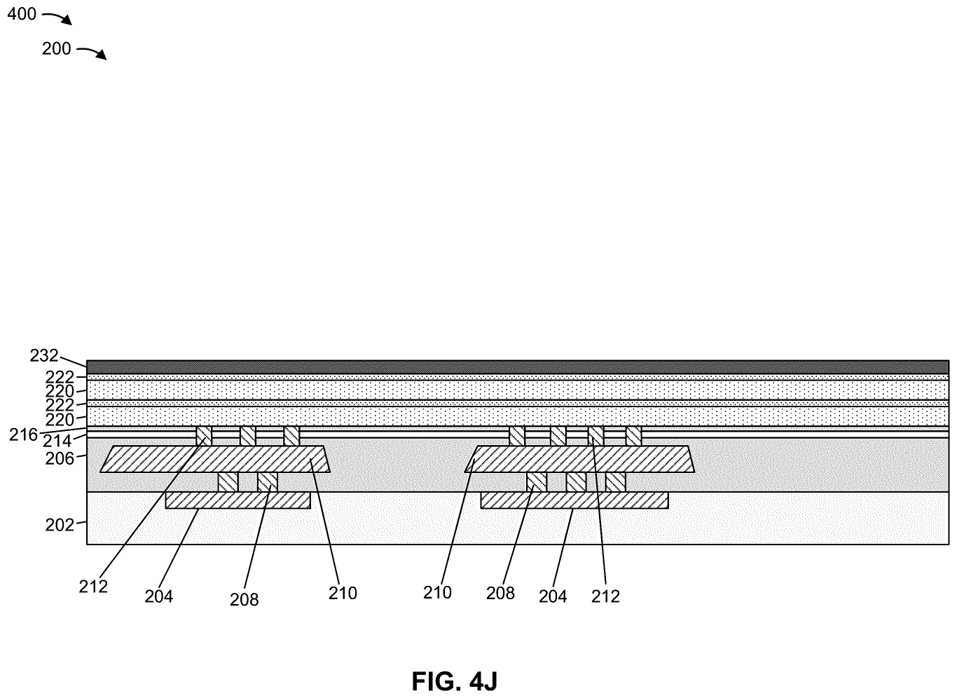

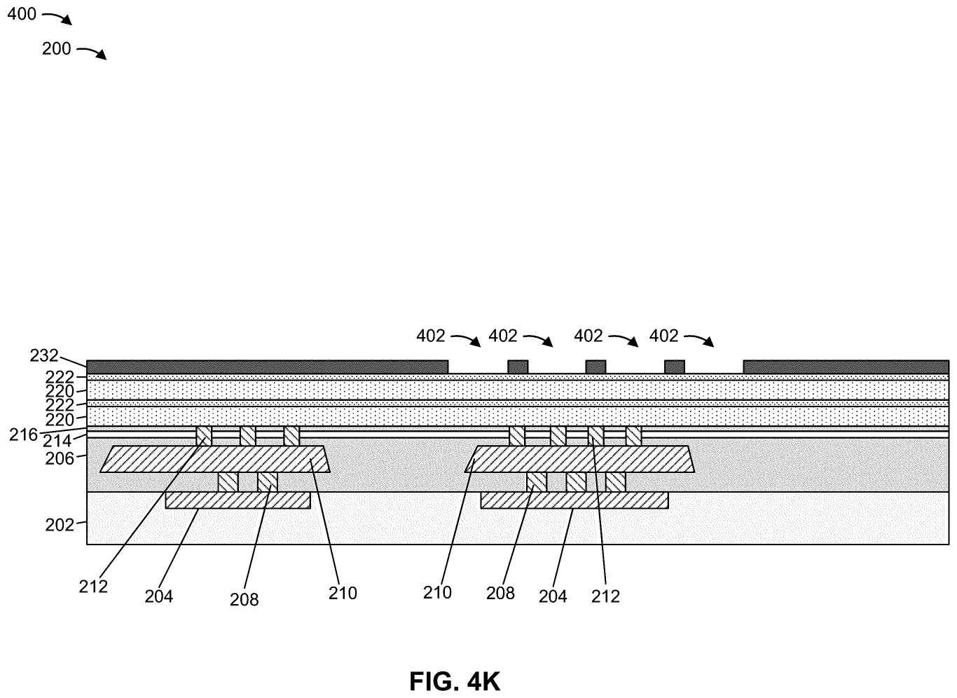

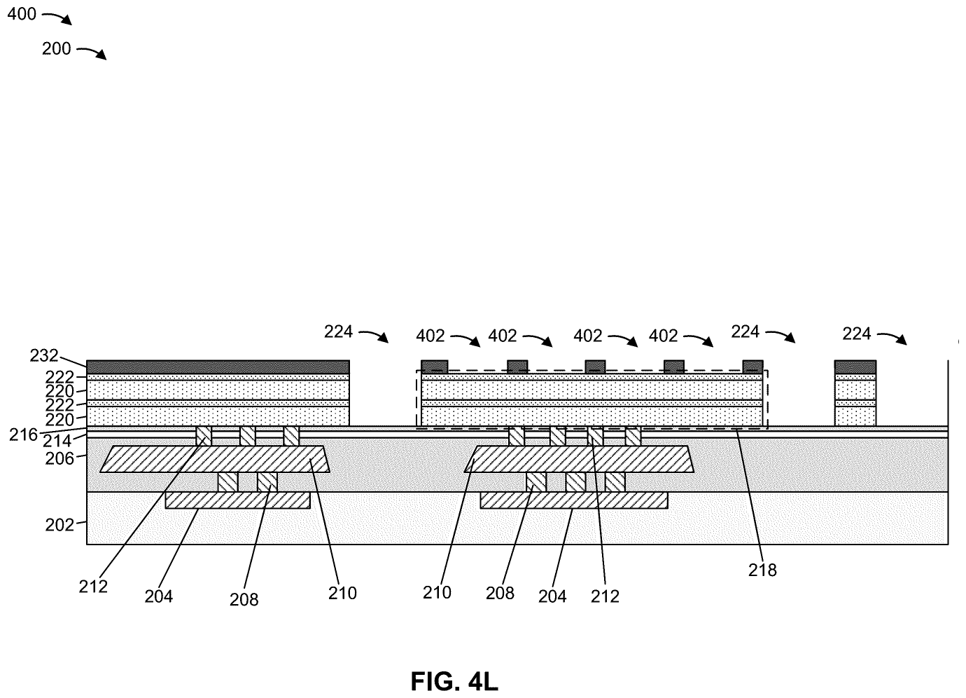

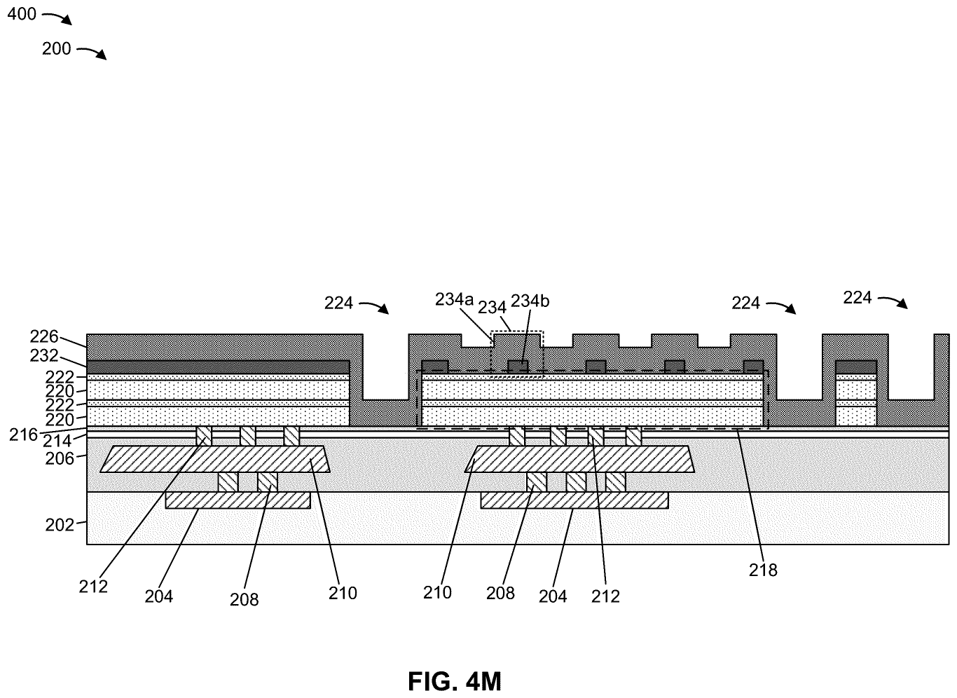

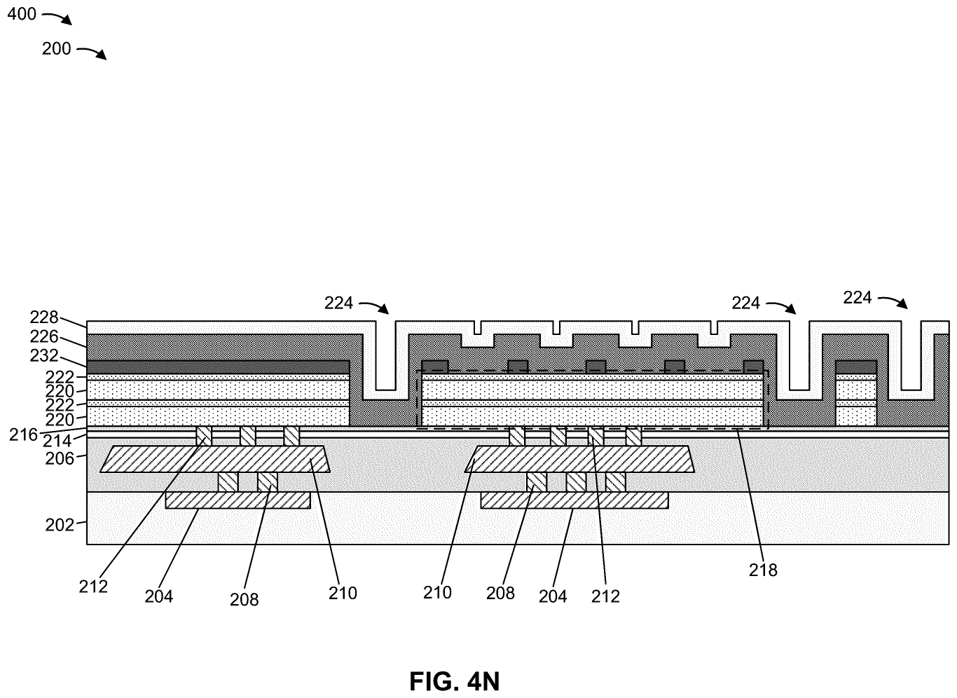

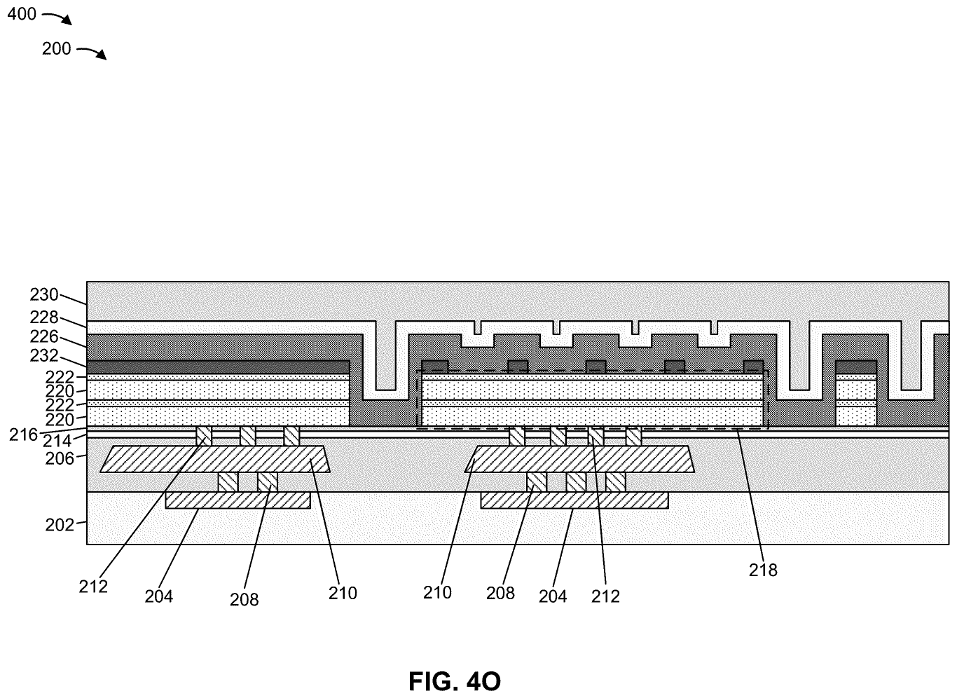

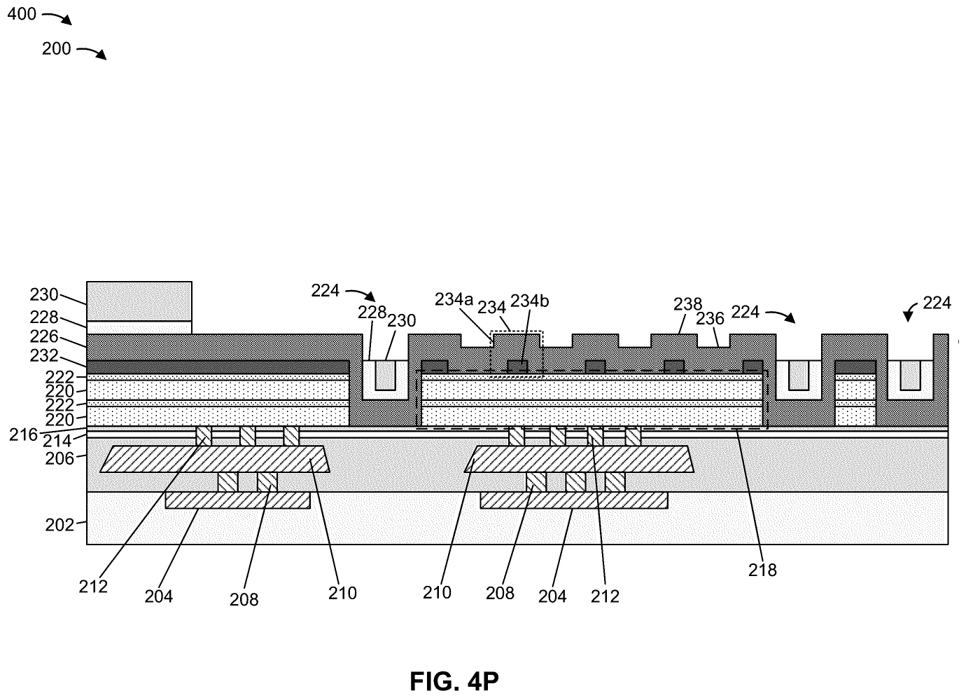

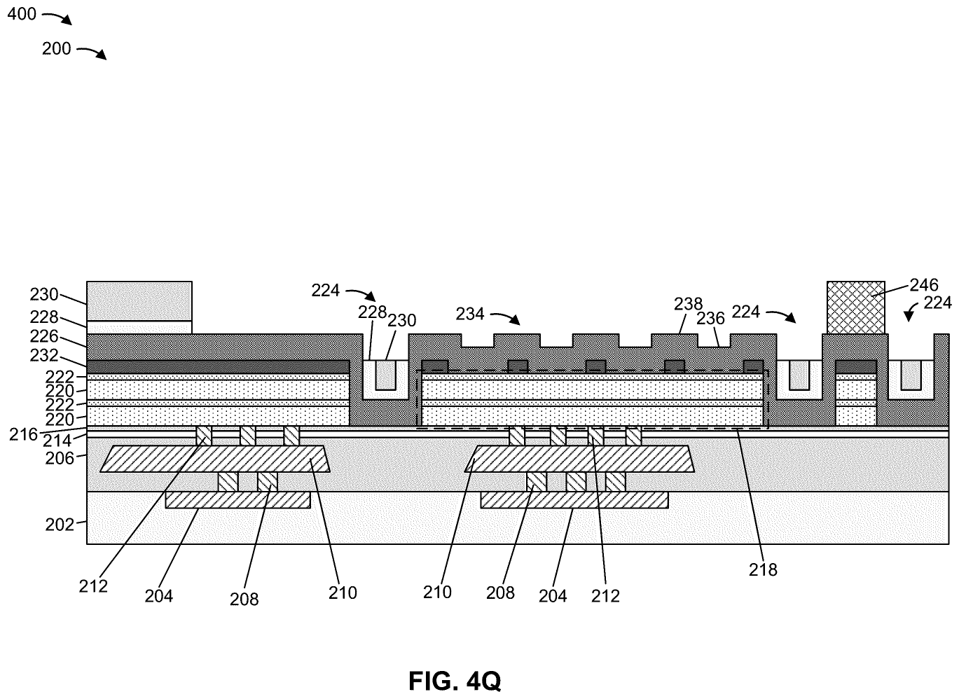

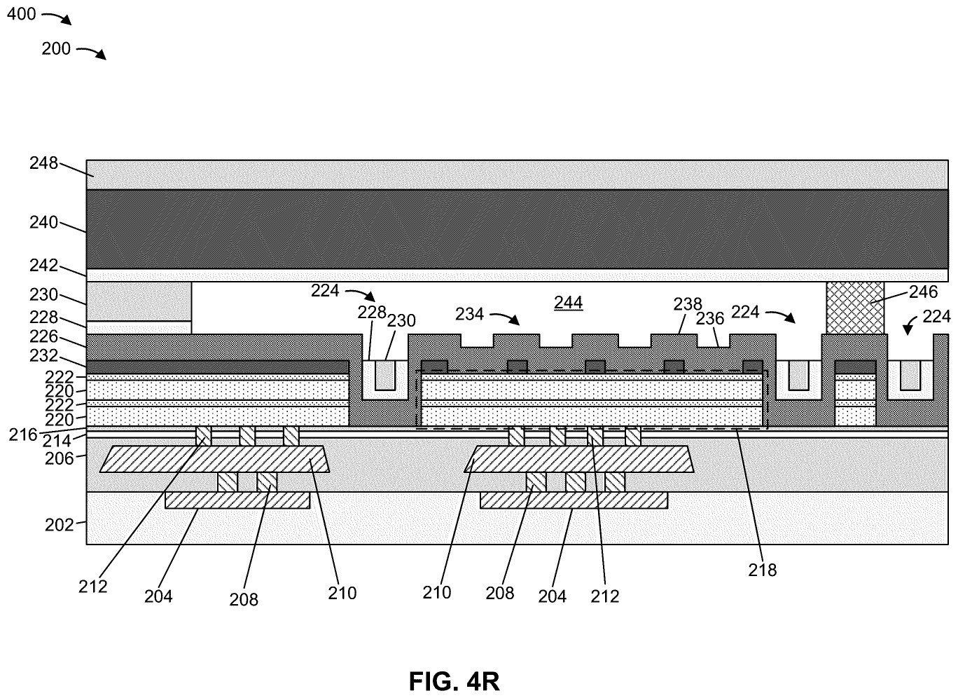

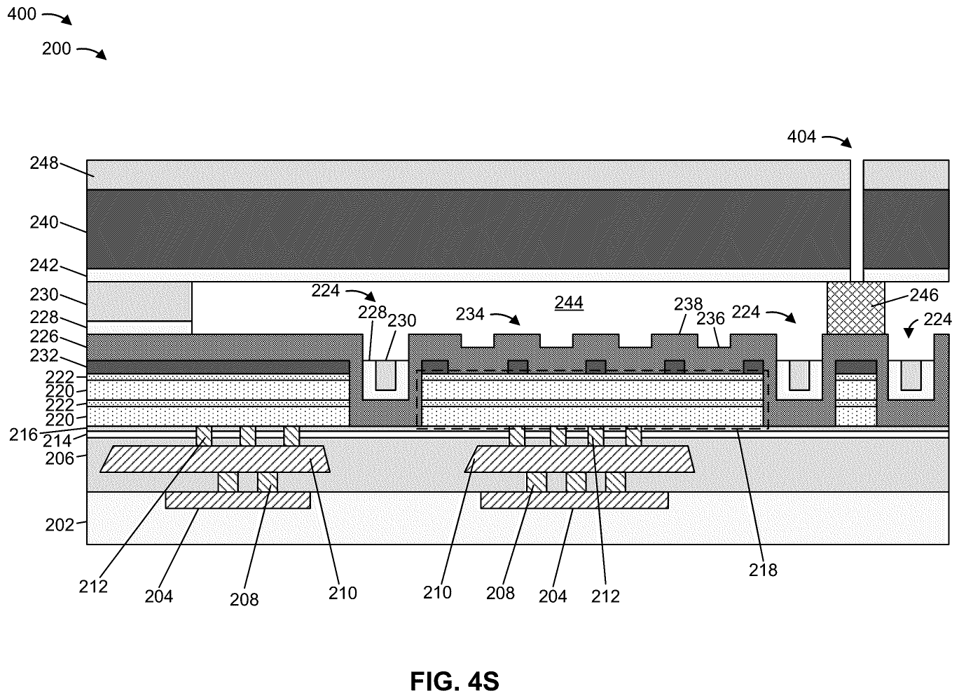

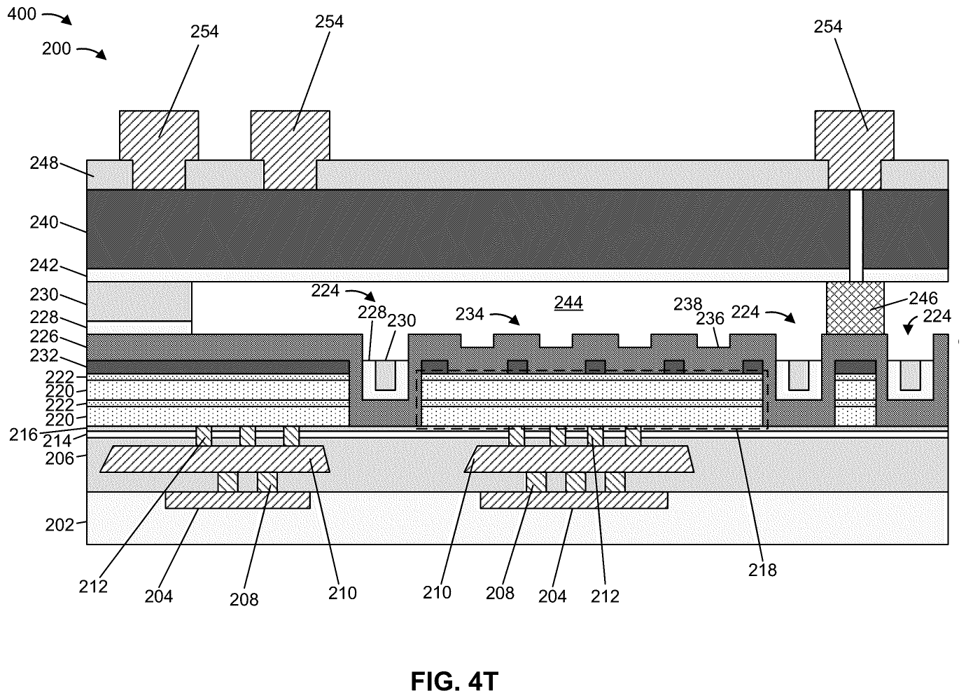

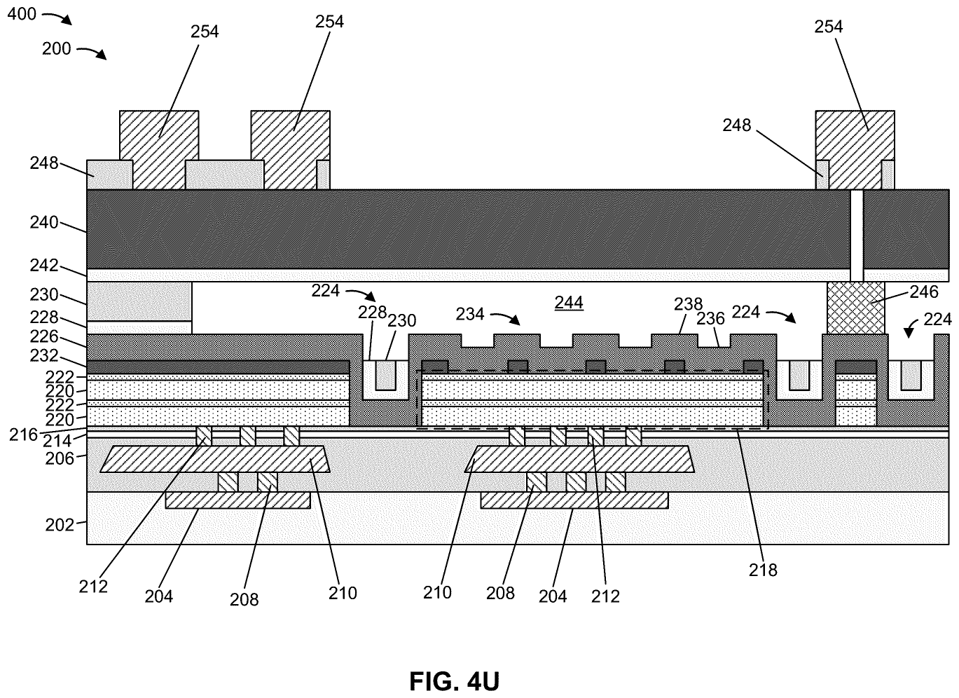

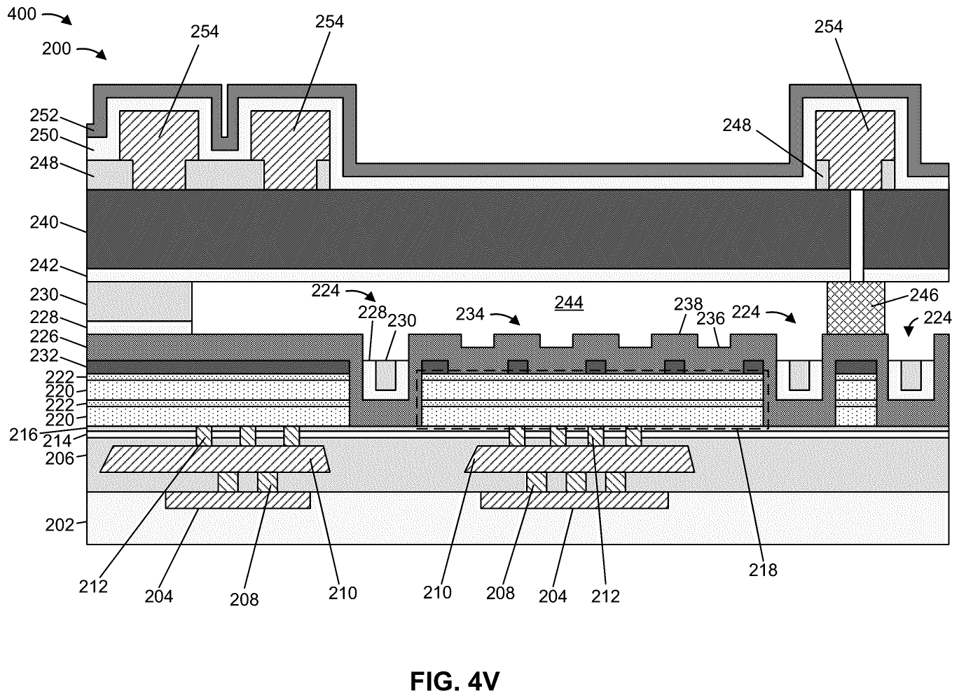

In some implementations, one or more of the semiconductor processing tools 102-114 may perform one or more semiconductor processing operations described herein. For example, one or more of the semiconductor processing 102-114 may perform other semiconductor processing operations described herein, such as in connection with FIGS. 4A-4V, 6A-6E, 8A-8H, and/or 10-12, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

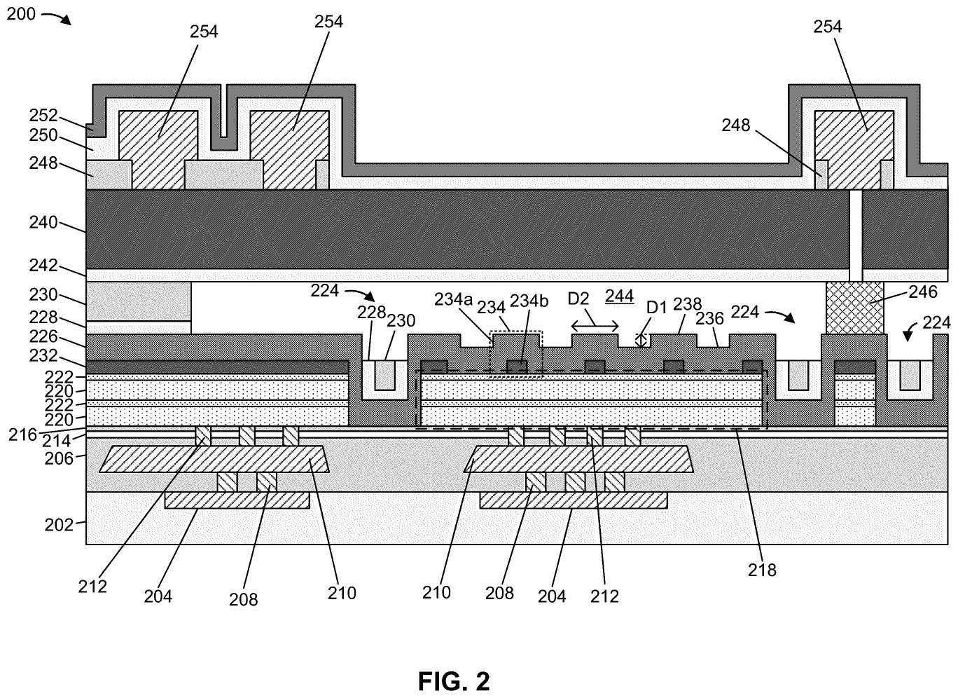

FIG. 2 is a diagram of an example semiconductor device 200 described herein. The semiconductor device 200 may be a MEMS device, such as an ultrasonic fingerprint sensor, among other examples. Additionally and/or alternatively, the semiconductor device 200 may include another type of MEMS device, such as a radio frequency (RF) switch, a motion sensor, and/or another type of MEMS device having a mechanical contact and high operating voltage.

As shown in FIG. 2, the semiconductor device 200 may include a substrate 202. The substrate 202 may include a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, or another type of semiconductor substrate. Alternatively, the substrate 202 may include a dielectric substrate that is included over a semiconductor wafer (e.g., a silicon wafer). The semiconductor device 200 may be cut or diced from the semiconductor wafer after or as a part of manufacturing of the semiconductor device 200. The semiconductor wafer may be a round/circular wafer having an approximately 200 mm diameter, an approximately 300 mm diameter, or another diameter, such as 450 mm, among other examples. The substrate 202 may be any square, rectangular, curved, or otherwise non-circular workpiece, such as a polygonal substrate.

The semiconductor device 200 may include one or more conductive structures 204 disposed in the substrate 202. The conductive structures 204 may include electrically conductive metallization layers that are electrically connected with one or more semiconductor devices (not shown) included in the substrate 202, such as one or more active semiconductor devices (e.g., transistors), one or more passive semiconductor devices (e.g., capacitors, resistors, inductors), and/or one or more semiconductor devices of another type.

As further shown in FIG. 2, the semiconductor device 200 may include an interconnect region 206 over and/or on the substrate 202. The interconnect region 206 may include one or more dielectric layers and one or more conductive structures in the one or more dielectric layers.

The one or more dielectric layers may include an oxide-containing material, a nitride-containing material, a silicon oxide (SiOₓ), a silicon nitride (SiₓN_{y}), a silicon oxynitride (SiON), fluoride-doped silicate glass (FSG), silicon carbon nitride (SiCN), silicon oxycarbide (SiOC), and/or another dielectric material, among other examples.

The one or more conductive structures may include one or more interconnect structures 208, one or more metallization layers 210, and/or one or more interconnect structures 212, among other examples. The one or more conductive structures may include one or more electrically conductive materials, such as platinum (Pt), titanium (Ti), ruthenium (Ru), cobalt (Co), tungsten (W), copper (Cu), molybdenum (Mo), an electrically conductive metallic material, an electrically conductive ceramic material, a metal alloy material, another electrically conductive material, or a combination thereof. The one or more interconnect structures 208 and the one or more interconnect structures 212 may each include a via, a conductive pillar, a through silicon via (TSV), a through insulator via (TIV), a trench, and/or another type of interconnect structure. The one or more metallization layers 210 may each include a conductive trace, a trench, and/or another type of metallization layer.

The one or more interconnect structures 208 may be included over and/or on the one or more conductive structures 204. The one or more interconnect structures 208 may be electrically coupled and/or physically coupled with the one or more conductive structures 204. The one or more metallization layers 210 may be included over and/or on the one or more interconnect structures 208. The one or more metallization layers 210 may be electrically coupled and/or physically coupled with the one or more interconnect structures 208. The one or more interconnect structures 212 may be included over and/or on the one or more metallization layers 210. The one or more interconnect structures 212 may be electrically coupled and/or physically coupled with the one or more metallization layers 210.

The one or more metallization layers 210 may extend through one or more dielectric layers above the interconnect region 206. The one or more dielectric layers may include a dielectric layer 214 over and/or on the interconnect region 206, a dielectric layer 216 over and/or on the dielectric layer 214, and/or another dielectric layer, among other examples. The dielectric layers 214 and 216 may each include an oxide-containing material, a nitride-containing material, a silicon oxide (SiOₓ), a silicon nitride (SiₓN_{y}), a silicon oxynitride (SiON), fluoride-doped silicate glass (FSG), silicon carbon nitride (SiCN), silicon oxycarbide (SiOC), and/or another dielectric material, among other examples. In some implementations, the dielectric layer 214 and the dielectric layer 216 include different dielectric materials. For example, the dielectric layer 214 may include a nitride-containing dielectric material and the dielectric layer 216 may include an oxide-containing dielectric material. In some implementations, the dielectric layer 214 and the dielectric layer 216 include the same dielectric material or the same combination of dielectric materials.

As further shown in FIG. 2, the semiconductor device 200 may include a sensing electrode 218. The sensing electrode 218 may be included in a CMUT that is included in the semiconductor device 200. For example, the sensing electrode 218 may correspond to a bottom electrode of the CMUT included in the semiconductor device 200. The sensing electrode 218 may be formed from a plurality of layers included in the semiconductor device 200. For example, the sensing electrode 218 may include a plurality of alternating layers of electrically conductive materials, including alternating metal layers 220 and metal nitride layers 222. The metal layers 220 may include platinum (Pt), titanium (Ti), ruthenium (Ru), cobalt (Co), tungsten (W), copper (Cu), molybdenum (Mo), tantalum (Ta), aluminum copper (AlCu), and/or another metal material, among other examples. The metal nitride layers 222 may include titanium nitride (TiN), tantalum nitride (TaN), and/or another electrically conductive metal nitride material.

In some implementations, a thickness of the metal layers 220 is greater than a thickness of the metal nitride layers 222. For example, the thickness of a metal layer 220 may be approximately 2 times to approximately 4 times the thickness of a metal nitride layer 222. However, other values for the range are within the scope of the present disclosure. In some implementations, the thickness of a metal layer 220 is included in a range of approximately 750 angstroms to approximately 1250 angstroms. However, other values for the range are within the scope of the present disclosure. In some implementations, the thickness of a metal nitride layer 222 is included in a range of approximately 200 angstroms to approximately 300 angstroms. However, other values for the range are within the scope of the present disclosure.

The sensing electrode 218 may be electrically isolated from other regions of the semiconductor device 200 by a plurality of isolation trenches 224. Thus, the sensing electrode 218 may be included between a plurality of isolation trenches 224. The isolation trenches 224 may provide protection from electrical current leakage between adjacent sensing electrodes 218. An isolation trench 224 may include a portion of a sensing dielectric layer 226, a portion of a nitride layer 228 (e.g., a dielectric layer), and a portion of a high-density plasma (HDP) oxide layer 230 (e.g., a dielectric layer), among other examples. The sensing dielectric layer 226 may continuously extend through a plurality of isolation trenches 224 and over the top of the sensing electrode 218 included between the plurality of isolation trenches. Alternatively, the sensing dielectric layer 226 may be segmented such that discontinuities are included in the sensing dielectric layer 226 between the isolation trenches 224.

The sensing dielectric layer 226 may be included over and/or on the sensing electrode 218 to enable the CMUT of the semiconductor device 200 to operate in a contact mode. Moreover, the sensing dielectric layer 226 may be included over and/or on the sensing electrode 218 to provide a dielectric layer that enables the capacitive property of the CMUT. The sensing dielectric layer 226 may include a plasma enhanced oxide (PEOx), a plasma enhanced nitride, an aluminum oxide (AlₓO_{y}), and/or another dielectric material. In some implementations, the sensing dielectric layer 226 is deposited using a PECVD technique (e.g., for a PEOx, a plasma enhanced nitride such as a plasma enhanced silicon nitride (SiₓN_{y}), and/or a plasma enhanced silicon oxynitride (SiON)). In some implementations, the sensing dielectric layer 226 is deposited using an ALD technique (e.g., for aluminum oxide (AlₓO_{y})).

Over the sensing electrode 218, portions of a dielectric layer 232 may be included between the sensing electrode 218 and the sensing dielectric layer 226. The dielectric layer 232 may include a plasma enhanced oxide (PEOx), a plasma enhanced nitride, an aluminum oxide (AlₓO_{y}), and/or another dielectric material. In some implementations, the dielectric layer 232 is deposited using a PECVD technique (e.g., for a PEOx, a plasma enhanced nitride such as a plasma enhanced silicon nitride (SiₓN_{y}), and/or a plasma enhanced silicon oxynitride (SiON)). In some implementations, the dielectric layer 232 is deposited using an ALD technique (e.g., for aluminum oxide (AlₓO_{y})). The portions of the dielectric layer 232 may be included such that a plurality of contact pedestal structures 234 are included above the sensing electrode 218 and between the isolation trenches 224. A contact pedestal structure 234 may include a portion 234a of the sensing dielectric layer 226 over a portion 234b of the dielectric layer 232.

As shown in FIG. 2, a top surface 236 of sensing dielectric layer 226 between adjacent contact pedestal structures 234 and a top surface 238 of the sensing dielectric layer 226 on a contact pedestal structure 234 may be at different heights in the semiconductor device 200. A dimension D1 of the semiconductor device 200 may correspond to a difference in height between the top surface 236 and the top surface 238. In some implementations, the dimension D1 may be included in a range of approximately 50 angstroms to approximately 500 angstroms to prevent or reduce the likelihood of stiction of an actuation membrane 240 to the sensing dielectric layer 226 while enabling sufficient deformation of the actuation membrane 240 (e.g., a sufficient amount of stroke). If the dimension D1 is less than approximately 50 angstroms, the actuation membrane 240 may contact the top surface 236 of the sensing dielectric layer 226 between contact pedestal structures 234 during operation of the CMUT, which may cause the sensing dielectric layer 226 to wear out between contact pedestal structures 234. This may degrade the breakdown voltage of the CMUT, which may cause the CMUT to no longer function. However, the dimension D1 may be included in another range, and ranges other than approximately 50 angstroms to approximately 500 angstroms are within the scope of the present disclosure.

In some implementations, a dimension D2 corresponding to a width of a contact pedestal structure 234 may be based on the thickness of the sensing dielectric layer 226. For example, the dimension D2 may be selected such that the thickness of the sensing dielectric layer 226 is approximately less than or equal to 10% of the dimension D2 (e.g., 2,000 angstrom thickness for the sensing dielectric layer 226 if the contact pedestal structure width is approximately 0.2 microns). As another example, the dimension D2 may be selected such that the thickness of the sensing dielectric layer 226 is included in a range of approximately 5% to approximately 10% of the width of a contact pedestal structure 234 (e.g., 4,000 angstrom thickness for the sensing dielectric layer 226 if the contact pedestal structure width is approximately 0.4 microns to approximately 0.8 microns).

The semiconductor device 200 may include the actuation membrane 240 of the CMUT. The actuation membrane 240 may be the actuator of the CMUT that selectively vibrates to generate an ultrasonic signal or vibrates based on reception of an ultrasonic signal. The actuation membrane 240 may include one or more layers of silicon (Si), may include a portion of a silicon wafer, and/or may include another type of structure. In some implementations, the actuation membrane 240 is formed from a bulk silicon wafer and is bonded to the semiconductor device 200. In some implementations, a dielectric coating 242 is formed on the actuation membrane 240 as part of a silicon on insulator (SOI) wafer manufacturing process. The dielectric coating 242 may include a thermal oxide (THOx) and/or another type of dielectric material. The dielectric coating 242 may be included on the underside of the actuation membrane 240 to achieve a sufficiently high breakdown voltage, along with the sensing dielectric layer 226, to enable the CMUT to operate at high voltages.

The actuation membrane 240 may be spaced apart from the contact pedestal structures 234 and the sensing dielectric layer 226 by a cavity 244. The cavity 244 may include an airgap or space that is pumped to a vacuum that enables the actuation membrane 240 to be displaced and to vibrate. In some implementations, the actuation membrane 240 may be operated in a collapsed mode where the actuation membrane 240 is stretched against the sensing dielectric layer 226. The contact pedestal structures 234 may be included to prevent or reduce the likelihood of stiction between the actuation membrane 240 and the sensing dielectric layer 226.

The cavity 244 may be formed from bonding the actuation membrane 240 to the HDP oxide layer 230 and a pressure port 246. The HDP oxide layer 230 and the pressure port 246 may function as standoffs for the actuation membrane 240, which enables the cavity 244 to be formed between the actuation membrane 240 and the contact pedestal structures 234 and the sensing dielectric layer 226. The pressure port 246 may be utilized to control, adjust, create, and/or otherwise affect pressure inside the cavity 244 after or during the bonding of the actuation membrane 240 and the semiconductor device 200.

Above the actuation membrane 240, various dielectric layers may be included, such as a dielectric layer 248, a capping layer 250, and/or a passivation layer 252, among other examples. The dielectric layer 248, the capping layer 250, and the passivation layer 252 may each include an oxide-containing material, a nitride-containing material, a silicon oxide (SiOₓ), a silicon nitride (SiₓN_{y}), a silicon oxynitride (SiON), fluoride-doped silicate glass (FSG), silicon carbon nitride (SiCN), silicon oxycarbide (SiOC), and/or another dielectric material, among other examples. Two or more of the dielectric layer 248, the capping layer 250, and the passivation layer 252 may include different dielectric materials. Two or more of the dielectric layer 248, the capping layer 250, and the passivation layer 252 may include the same dielectric materials.

Conductive contacts 254 may be included on, and may be electrically coupled with, the actuation membrane 240. The conductive contacts 254 may include platinum (Pt), titanium (Ti), ruthenium (Ru), cobalt (Co), tungsten (W), copper (Cu), molybdenum (Mo), tantalum (Ta), aluminum copper (AlCu), and/or another metal material, among other examples. The conductive contacts 254 may enable various voltages to be applied to the actuation membrane 240.

In this way, the semiconductor device 200 may include a sensing electrode 218 above a substrate 202 and between a plurality of isolation trenches 224. The semiconductor device 200 may include a plurality of portions 234b of a first dielectric layer (e.g., a dielectric layer 232) on the sensing electrode 218. The semiconductor device 200 may include a portion 234a of a second dielectric layer (e.g., a sensing dielectric layer 226) on the sensing electrode 218 and on the plurality of portions 234b of the first dielectric layer. The semiconductor device 200 may include an actuation membrane 240 above the second dielectric layer, where the actuation membrane 240 and the second dielectric layer are spaced apart by a cavity 244. The semiconductor device 200 may include a third dielectric layer (e.g., a dielectric coating 242) on the actuation membrane 240. The third dielectric layer is between the actuation membrane 240 and the cavity 244. The thickness of the portion 234a of the second dielectric layer is greater than a thickness of the third dielectric layer.

As indicated above, FIG. 2 is provided as an example. Other examples may differ from what is described with regard to FIG. 2.

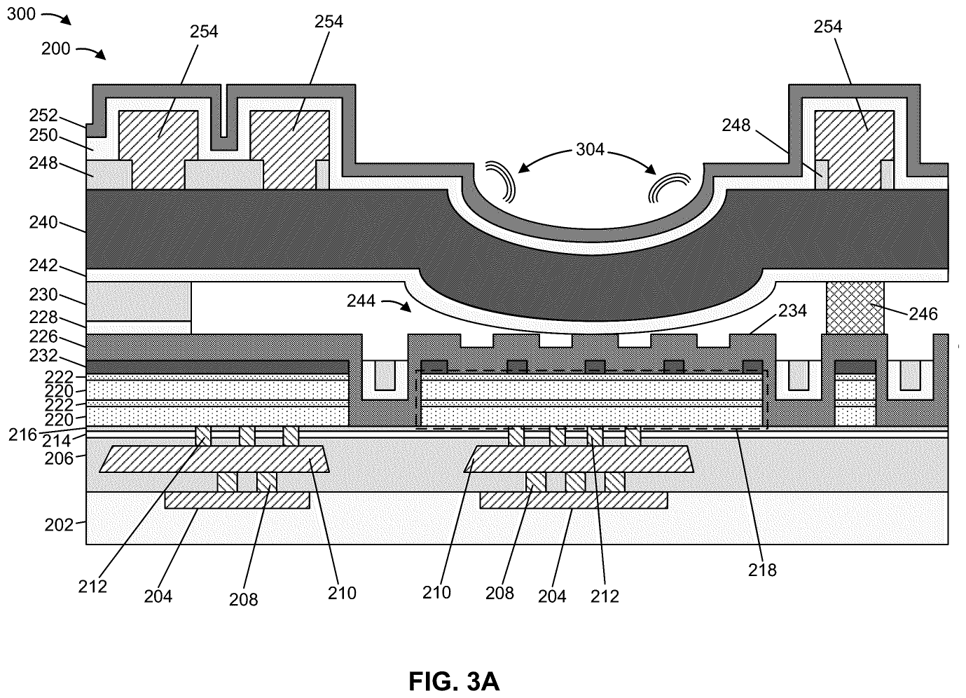

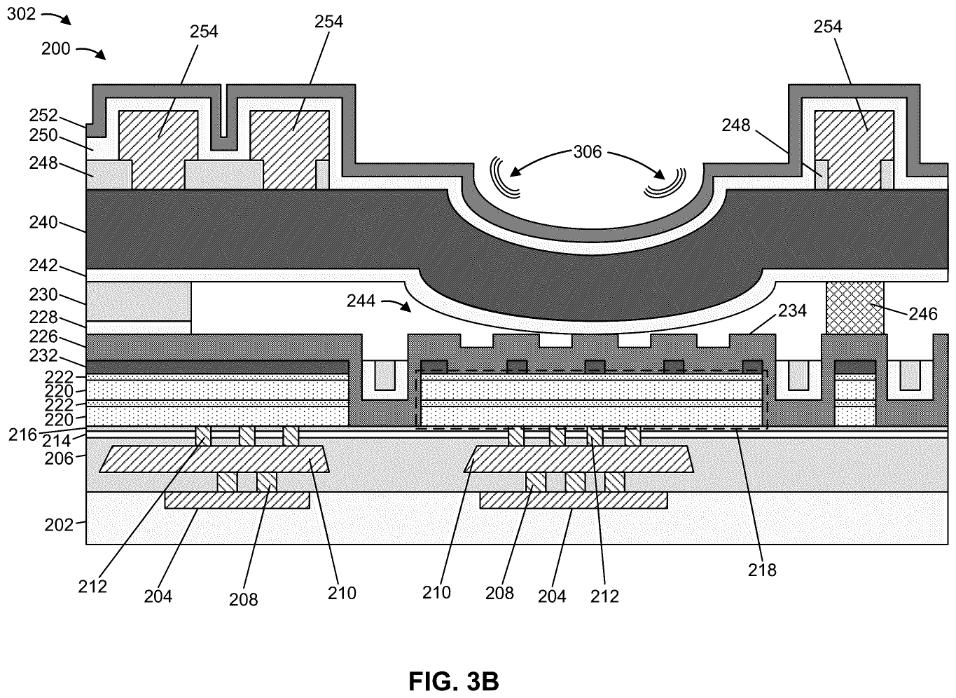

FIGS. 3A and 3B are diagrams of example implementations of operating modes of the CMUT of the semiconductor device 200 described herein. FIG. 3A illustrates an example implementation 300 of the CMUT of the semiconductor device 200 being configured to operate in an ultrasonic transmission mode. FIG. 3B illustrates an example implementation 302 of the CMUT of the semiconductor device 200 being configured to operate in an ultrasonic reception mode.

In the ultrasonic transmission mode illustrated in FIG. 3A, a driving signal such as an alternating current (AC) voltage (Vₐc) may be applied to the actuation membrane 240 (e.g., through the conductive contacts 254) and to the sensing electrode 218 (e.g., through the conductive structures 204, 208, 210, and/or 212) to cause the actuation membrane 240 to be displaced, which results in the CMUT emitting an ultrasonic signal 304. The displacement of the actuation membrane 240 causes the actuation membrane 240 to vibrate, thereby resulting in the CMUT emitting the ultrasonic signal 304.

In the ultrasonic reception mode, the actuation membrane 240 may receive an ultrasonic signal 306. The ultrasonic signal 306 may be a reflected version of the ultrasonic signal 304. For example, the ultrasonic signal 306 may be a reflected version of the ultrasonic signal 304 that is reflected off of a finger that is placed over the CMUT. The ultrasonic signal 306 may cause displacement of the actuation membrane 240. The displacement of the actuation membrane 240 causes an electric field between the ultrasonic signal 306 and the sensing electrode 218 to vary with time. The actuation membrane 240, the sensing electrode 218, and the cavity 244 and the dielectric layers (e.g., the sensing dielectric layer 226, the dielectric coating 242) between the actuation membrane 240 and the sensing electrode 218 operate as a capacitor. The capacitive property is used to transform the time-varying electric field generated based on the ultrasonic signal 306 to a time-varying electric signal (e.g., an AC voltage (V_{ac})), which may be used to generate a fingerprint scan of the finger that is placed over the CMUT.

In the ultrasonic transmission mode and in the ultrasonic reception mode, the CMUT may be configured to operate in a particular operational mode, such as a free-standing mode or a collapsed mode. In a free-standing mode, the actuation membrane of the CMUT is operated using a direct current (DC) voltage bias (V_{dc-bias}) that is less than a collapse voltage (V_{collapse}) of the actuation membrane 240. This results in the actuation membrane 240 being able to vibrate freely, which results in fewer reliability concerns relative to the collapsed mode. However, the sound pressure that may be achievable by the CMUT in the free-standing mode is less than the sound pressure that may be achievable by the CMUT in the collapsed mode. In the collapsed mode (which is shown in FIGS. 3A and 3B), the actuation membrane 240 of the CMUT is operated using a V_{dc-bias} that is greater than the V_{collapse} of the actuation membrane 240, resulting in the actuation membrane 240 being stretched against the contact pedestal structures 234 of the underlying sensing dielectric layer 226. The collapsed mode may provide greater sound pressure output and/or greater sensing sensitivity for the CMUT, and may enable the frequency response of the actuation membrane 240 to be adjustable.

The CMUT of the semiconductor device 200 may be configured to operate at relatively high voltages for the V_{dc-bias} of the actuation membrane 240 (e.g., to achieve collapsing of the actuation membrane 240) and/or for the drive signal (e.g., the Vₐc). For example, the V_{dc-bias} of the actuation membrane 240 and/or the V_{ac} may be included in a range of approximately 100 volts to approximately 135 volts or greater. The high voltage(s) may cause the actuation membrane 240 to rub against the contact pedestal structures 234 during operation of the CMUT in the collapsed mode, which may cause the dielectric coating 242 on the underside of the actuation membrane 240 to wear out in areas in which the actuation membrane 240 contacts the contact pedestal structures 234.

If the dielectric coating 242 were to wear out, the breakdown voltage of the CMUT may reduce to the point where the CMUT can no longer operate because the high voltage(s) may exceed the reduced breakdown voltage of the CMUT. Simply increasing the thickness of the dielectric coating 242 to mitigate wear out of the dielectric coating 242 may increase the stiffness of the actuation membrane 240, thereby resulting in the actuation membrane 240 being unable to operate at ultrasonic frequencies.

The sensing dielectric layer 226 may be formed such that the thickness of the sensing dielectric layer 226 may extend the operational life of the CMUT while enabling the CMUT to accommodate sufficiently high voltages for collapsed mode operation and to enable the actuation membrane 240 to still operate at ultrasonic frequencies. For example, the thickness of the sensing dielectric layer 226 may be greater than the thickness of the dielectric coating 242 on the underside of the actuation membrane 240. While the dielectric strength of the dielectric coating 242 may be greater than the dielectric strength of the sensing dielectric layer 226, the greater thickness of the sensing dielectric layer 226 may enable the sensing dielectric layer 226 to provide sufficient dielectric permittivity to enable the CMUT to maintain a sustained high breakdown voltage so that the CMUT can still operate at sufficiently high voltages even if the dielectric coating 242 does wear out. In this way, the thickness of the sensing dielectric layer 226 enables the CMUT to operate in the collapsed mode, which enables the CMUT to achieve greater sound pressure output relative to other operational modes and enables the frequency response of the CMUT to be adjustable, thereby enabling the frequency response to be optimized for specific use cases and applications. Moreover, the thickness of the sensing dielectric layer 226 may enable the CMUT to operate at a sustained high breakdown voltage over a longer period of time (e.g., relative to CMUTs that include a thinner sensing dielectric layer), which reduces the likelihood of premature wear out and extends the operational life of the CMUT.

The thickness of the dielectric coating 242 may be included in a range of greater than 0 angstroms to approximately 3,000 angstroms. In some implementations, the dielectric coating 242 may be omitted from the actuation membrane 240 if the sensing dielectric layer 226 is sufficiently thick to provide a sufficient breakdown voltage. However, in some cases, omitting the dielectric coating 242 may result in residual electrical charges left on the sensing dielectric layer 226 during operation of the CMUT, which may cause the DC bias voltage to drift during operation of the CMUT. If the thickness of the dielectric coating 242 is greater than approximately 3,000 angstroms, the stiffness of the actuation membrane 240 may be increased to the point where the actuation membrane 240 may not be able to operate at ultrasonic frequencies. Moreover, the capacitance between the actuation membrane 240 and the sensing electrode 218 may be too high, which may result in increased/slower response times for the CMUT. If the thickness of the dielectric coating 242 is in the range of greater than 0 angstroms to approximately 3,000 angstroms, the actuation membrane 240 may be able to operate at ultrasonic frequencies and the likelihood of DC bias voltage during operation of the CMUT may be reduced. However, other values and/or ranges for the thickness of the dielectric coating 242 are within the scope of the present disclosure.

The thickness of the sensing dielectric layer 226 is greater than the thickness of the dielectric coating 242. For example, the thickness of the sensing dielectric layer 226 may be included in a range of approximately 1,900 angstroms to approximately 4,000 angstroms. In some implementations, the thickness of the sensing dielectric layer 226 is based on the maximum operating voltage (Vₘₐₓ), which may correspond to the maximum AC voltage or the maximum DC bias voltage of the CMUT. For example, the thickness of the sensing dielectric layer 226 may correspond to a value in a range of approximately

$$\frac{{V}_{max}}{1 , 000 V / μm}$$

to approximately

$$\frac{{V}_{max}}{500 V / μm} .$$

As an example, if Vₘₐₓ is 220 volts, the thickness of the sensing dielectric layer 226 may be included in a range of approximately 2,200 angstroms to approximately 4,400 angstroms. Selecting the value of the thickness for the sensing dielectric layer 226 from the range of approximately

$$\frac{{V}_{max}}{1 , 000 V / μm}$$

to approximately

$$\frac{{V}_{max}}{500 V / μm}$$

enables a sufficiently high breakdown voltage to be maintained for the CMUT (e.g., even in the event of wear out of the dielectric coating 242) while enabling sufficient driving static force and sufficient capacitance to be achieved for the CMUT. Selecting the value of the thickness for the sensing dielectric layer 226 from outside of the range of approximately

$$\frac{{V}_{max}}{1 , 000 V / μm}$$

to approximately

$$\frac{{V}_{max}}{500 V / μm}$$

may result in too low of breakdown voltage, too low of driving static force and/or too low of capacitance for the CMUT. However, other values and/or ranges other than approximately

$$\frac{{V}_{max}}{1 , 000 V / μm}$$

to approximately

$$\frac{{V}_{max}}{500 V / μm}$$

are within the scope of the present disclosure.

The thickness of the actuation membrane 240 may be included in a range of approximately 1 micron to approximately 30 microns. The actuation membrane 240 may not have sufficient mechanical strength at thicknesses less than approximately 1 micron, which may result in the actuation membrane 240 breaking during operation of the CMUT. The actuation membrane 240 may have sufficient mechanical strength to withstand operation of the CMUT at thicknesses greater than approximately 1 micron. The actuation membrane 240 may not have sufficient flexibility to operate at ultrasonic frequencies if the thickness of the actuation membrane 240 is greater than approximately 30 microns. The actuation membrane 240 may have sufficient flexibility to operate at ultrasonic frequencies at thicknesses less than approximately 30 microns. However, other values and/or ranges (e.g., other than approximately 1 micron to approximately 30 microns) for the thickness of the actuation membrane 240 are within the scope of the present disclosure.

A thickness of the sensing electrode 218 may be included in a range of approximately 400 angstroms to approximately 30,000 angstroms. The electrical resistance of the sensing electrode 218 may be too high at thicknesses less than approximately 400 angstroms, which may result in increased/slower response times for the CMUT. If the thickness of the sensing electrode 218 is greater than approximately 400 angstroms, the low electrical resistance of the sensing electrode 218 may enable reduced/faster response times for the CMUT. Moreover, thicknesses greater than approximately 30,000 angstroms for sensing electrode 218 may result in longer processing times (e.g., longer CMP times) for the sensing electrode 218 and a highly nonuniform surface for the sensing electrode 218, which may cause process defects in other layers and/or structures in the semiconductor device 200. Thicknesses of approximately 30,000 angstroms or less may result in reduced processing times (e.g., reduced CMP times) for the sensing electrode 218 and increased surface uniformity for the sensing electrode 218. However, other values and/or ranges (e.g., other than approximately 400 angstroms to approximately 30,000 angstroms) for the thickness of the sensing electrode 218 are within the scope of the present disclosure.

As indicated above, FIGS. 3A and 3B are provided as examples. Other examples may differ from what is described with regard to FIGS. 3A and 3B.

FIGS. 4A-4V are diagrams of an example implementation 400 of forming the semiconductor device 200 (or a portion thereof) described herein. In some implementations, one or more of the semiconductor processing operations described in connection with FIGS. 4A-4V may be performed using one or more of the semiconductor processing tools 102-114 described in connection with FIG. 1. In some implementations, one or more of the semiconductor processing operations described in connection with FIGS. 4A-4V may be performed using another semiconductor processing tool not shown in FIG. 1.

Turning to FIG. 4A, the substrate 202 may be provided. The substrate 202 may be provided as a semiconductor wafer, a semiconductor die, and/or another type of semiconductor substrate. In some implementations, the substrate 202 may be a doped substrate, such as a semiconductor substrate that is doped with one or more p-type dopants, a semiconductor substrate that is doped with one or more n-type dopants, and/or another type of doped substrate. In some implementations, the substrate 202 has a bulk resistivity (or volumetric resistivity) that is included in a range of approximately 1 ohm-centimeter to approximately 100 ohm-centimeters. However, other values for the range are within the scope of the present disclosure.

As shown in FIG. 4B, conductive structures 204 may be formed in the substrate 202. A deposition tool 102 and/or a plating tool 112 may be used to deposit the conductive structures 204 in a CVD operation, a PVD operation, an ALD operation, an electroplating operation, another deposition operation described above in connection with FIG. 1, and/or another suitable deposition operation. In some implementations, a seed layer is first deposited, and the conductive structures 204 are deposited on the seed layer. In some implementations, a planarization tool 110 may be used to planarize the conductive structures 204 after the conductive structures 204 are deposited.

As shown in FIG. 4C, a portion of the interconnect region 206 is formed over and/or on the substrate 202. A deposition tool 102 may be used to deposit one or more dielectric layers of the interconnection region 206 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, a planarization tool 110 may be used to planarize the one or more dielectric layers of the interconnection region 206 after the one or more dielectric layers of the interconnection region 206 are deposited.

As shown in FIG. 4D, interconnect structures 208 are formed in the one or more dielectric layers of the interconnection region 206. An interconnect structure 208 may be formed in a recess in the one or more dielectric layers such that the interconnect structure 208 is electrically coupled and/or physically coupled with a conductive structure 204. The recess may be formed in and/or through the one or more dielectric layers of the interconnection region 206. In particular, the recess may be formed over the conductive structure 204. The recess may be formed fully through the one or more dielectric layers of the interconnection region 206 such that the top surface of the conductive structure 204 is exposed through the recess.

In some implementations, a pattern in a photoresist layer is used to form the recess in the one or more dielectric layers of the interconnection region 206. In these implementations, a deposition tool 102 is used to form the photoresist layer on the one or more dielectric layers of the interconnection region 206. An exposure tool 104 is used to expose the photoresist layer to a radiation source to pattern the photoresist layer. A developer tool 106 is used to develop and removes portions of the photoresist layer to expose the pattern. An etch tool 108 is used to etch into the one or more dielectric layers of the interconnection region 206 based on the pattern to form the recess. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recess based on a pattern.

A deposition tool 102 and/or a plating tool 112 may be used to deposit the interconnect structure 208 over and/or on the conductive structure 204 in a CVD operation, a PVD operation, an ALD operation, an electroplating operation, another deposition operation described above in connection with FIG. 1, and/or another suitable deposition operation. In some implementations, a seed layer is first deposited, and the interconnect structure 208 is deposited on the seed layer. In some implementations, a planarization tool 110 may be used to planarize the interconnect structure 208 after the interconnect structure 208 is deposited.

As shown in FIG. 4E, another portion of the interconnect region 206 is formed over and/or on the interconnect region 206. A deposition tool 102 may be used to deposit one or more additional dielectric layers of the interconnection region 206 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, a planarization tool 110 may be used to planarize the one or more additional dielectric layers of the interconnection region 206 after the one or more additional dielectric layers of the interconnection region 206 are deposited.

As shown in FIG. 4F, metallization layers 210 are formed in the one or more additional dielectric layers of the interconnection region 206. A metallization layer 210 may be formed in a recess in the one or more additional dielectric layers such that the metallization layer 210 is electrically coupled and/or physically coupled with one or more of the interconnect structures 208. The recess may be formed in and/or through the one or more additional dielectric layers of the interconnection region 206. In particular, the recess may be formed over the one or more interconnect structures 208. The recess may be formed fully through the one or more additional dielectric layers of the interconnection region 206 such that top surfaces of the one or more interconnect structures 208 are exposed through the recess.

In some implementations, a pattern in a photoresist layer is used to form the recess in the one or more additional dielectric layers of the interconnection region 206. In these implementations, a deposition tool 102 is used to form the photoresist layer on the one or more additional dielectric layers of the interconnection region 206. An exposure tool 104 is used to expose the photoresist layer to a radiation source to pattern the photoresist layer. A developer tool 106 is used to develop and removes portions of the photoresist layer to expose the pattern. An etch tool 108 is used to etch into the one or more additional dielectric layers of the interconnection region 206 based on the pattern to form the recess. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recess based on a pattern.

A deposition tool 102 and/or a plating tool 112 may be used to deposit the metallization layer 210 over and/or on the one or more interconnect structures 208 in a CVD operation, a PVD operation, an ALD operation, an electroplating operation, another deposition operation described above in connection with FIG. 1, and/or another suitable deposition operation. In some implementations, a seed layer is first deposited, and the metallization layer 210 is deposited on the seed layer. In some implementations, a planarization tool 110 may be used to planarize the interconnect structure 208 after the metallization layer 210 is deposited.

As shown in FIG. 4G, one or more dielectric layers, such as the dielectric layer 214 and/or the dielectric layer 216, may be formed over and/or on the interconnect region 206. In some implementations, the dielectric layer 214 is formed over and/or on the interconnect region 206, and the dielectric layer 216 is formed over and/or on the dielectric layer 214. A deposition tool 102 may be used to deposit the dielectric layer 214 and/or the dielectric layer 216 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, a planarization tool 110 may be used to planarize the one or more additional dielectric layers of the interconnection region 206 after the one or more additional dielectric layers of the interconnection region 206 are deposited.

As shown in FIG. 4H, interconnect structures 212 may be formed in the dielectric layers 214, 216, and into the interconnection region 206. An interconnect structure 212 may be formed in a recess in the dielectric layers 214, 216, and in the interconnection region 206, such that the interconnect structure 212 is electrically coupled and/or physically coupled with a metallization layer 210. The recess may be formed in and/or through the dielectric layers 214, 216, and into a portion of the interconnection region 206. In particular, the recess may be formed over the metallization layer 210. The recess may be formed such that the top surface of the metallization layer 210 is exposed through the recess.

In some implementations, a pattern in a photoresist layer is used to form the recess in the dielectric layers 214, 216, and into the interconnection region 206. In these implementations, a deposition tool 102 is used to form the photoresist layer on the dielectric layer 216. An exposure tool 104 is used to expose the photoresist layer to a radiation source to pattern the photoresist layer. A developer tool 106 is used to develop and removes portions of the photoresist layer to expose the pattern. An etch tool 108 is used to etch into the dielectric layers 214, 216, and into the interconnection region 206 based on the pattern to form the recess. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recess based on a pattern.

A deposition tool 102 and/or a plating tool 112 may be used to deposit the interconnect structure 212 over and/or on the metallization layer 210 in a CVD operation, a PVD operation, an ALD operation, an electroplating operation, another deposition operation described above in connection with FIG. 1, and/or another suitable deposition operation. In some implementations, a seed layer is first deposited, and the interconnect structure 212 is deposited on the seed layer. In some implementations, a planarization tool 110 may be used to planarize the interconnect structure 208 after the interconnect structure 212 is deposited.

As shown in FIG. 4I, a stack of alternating metal layers 220 and metal nitride layers 222 may be formed over and/or on the dielectric layer 216. A deposition tool 102 and/or a plating tool 112 may be used to deposit the metal layers 220 in a CVD operation, a PVD operation, an ALD operation, an electroplating operation, another deposition operation described above in connection with FIG. 1, and/or another suitable deposition operation. In some implementations, a seed layer is first deposited, and a metal layer 220 is deposited on the seed layer. In some implementations, a planarization tool 110 may be used to planarize a metal layer 220 after the metal layer 220 is deposited. A deposition tool 102 may be used to deposit the metal nitride layers 222 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, a planarization tool 110 may be used to planarize a metal nitride layer 222 after the metal nitride layer 222 is deposited. In some implementations, the stack of alternating metal layers 220 and metal nitride layers 222 is annealed after the stack of alternating metal layers 220 and metal nitride layers 222 is deposited to remove voids and other discontinuities in the stack of alternating metal layers 220 and metal nitride layers 222.

As shown in FIG. 4J, the dielectric layer 232 may be formed over and/or on the stack of alternating metal layers 220 and metal nitride layers 222. A deposition tool 102 may be used to deposit the dielectric layer 232 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, a planarization tool 110 may be used to planarize the dielectric layer 232 after the dielectric layer 232 is deposited.

As shown in FIG. 4K, recesses 402 may be formed in the dielectric layer 232. The recesses 402 may be formed over a metallization stack that includes a conductive structure 204, one or more interconnect structures 208, a metallization layer 210, and/or one or more interconnect structures 212.

In some implementations, a pattern in a photoresist layer is used to form the recesses 402 in the dielectric layer 232. In these implementations, a deposition tool 102 is used to form the photoresist layer on the dielectric layer 232. An exposure tool 104 is used to expose the photoresist layer to a radiation source to pattern the photoresist layer. A developer tool 106 is used to develop and removes portions of the photoresist layer to expose the pattern. An etch tool 108 is used to etch into the dielectric layer 232 based on the pattern to form the recesses 402. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 402 based on a pattern.

As shown in FIG. 4L, isolation trenches 224 may be formed through the dielectric layer 232 and through the alternating stack of metal layers 220 and metal nitride layer 222. The isolation trenches 224 may be formed on opposing sides of the recesses 402. The formation of the isolation trenches 224 results in formation of the sensing electrode 218 of the CMUT of the semiconductor device 200. The isolation trenches 224 may be configured to electrically isolate the sensing electrode 218.

In some implementations, a pattern in a photoresist layer is used to form the isolation trenches 224 through the dielectric layer 232 and through the alternating stack of metal layers 220 and metal nitride layer 222. In these implementations, a deposition tool 102 is used to form the photoresist layer on the dielectric layer 232. An exposure tool 104 is used to expose the photoresist layer to a radiation source to pattern the photoresist layer. A developer tool 106 is used to develop and removes portions of the photoresist layer to expose the pattern. An etch tool 108 is used to etch through the dielectric layer 232 and through the alternating stack of metal layers 220 and metal nitride layer 222 based on the pattern to form the isolation trenches 224. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the isolation trenches 224 based on a pattern.

As shown in FIG. 4M, the sensing dielectric layer 226 may be formed on the semiconductor device 200. The sensing dielectric layer 226 may be formed on the dielectric layer 232 and in the isolation trenches 224. The sensing dielectric layer 226 may also be formed on the sensing electrode 218. A portion 234a of the sensing dielectric layer 226 over the sensing electrode 218 covers portions 234b of the dielectric layer 232, thereby resulting in formation of the contact pedestal structures 234 over the sensing electrode 218. A deposition tool 102 may be used to deposit the sensing dielectric layer 226 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, a deposition tool 102 is used to deposit the sensing dielectric layer 226 using a PECVD technique. The sensing dielectric layer 226 may be conformally deposited such that the sensing dielectric layer 226 conforms to the contours of the portions 234b of the dielectric layer 232, which may result in formation of the contact pedestal structures 234.

As shown in FIG. 4N, the nitride layer 228 may be formed on the sensing dielectric layer 226. The nitride layer 228 may be formed on the sensing dielectric layer 226 in the isolation trenches 224 and on the sensing dielectric layer 226 over the sensing electrode 218. A deposition tool 102 may be used to deposit the nitride layer 228 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. The nitride layer 228 may be conformally deposited such that the nitride layer 228 conforms to the contours of the sensing dielectric layer 226.

As shown in FIG. 4O, the HDP oxide layer 230 may be formed over and/or on the nitride layer 228. The HDP oxide layer 230 may be formed on the nitride layer 228 in the isolation trenches 224 and on the nitride layer 228 over the sensing electrode 218. A deposition tool 102 may be used to deposit the HDP oxide layer 230 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, the HDP oxide layer 230 is deposited using a high density plasma deposition technique to blanket deposit the HDP oxide layer 230.

As shown in FIG. 4P, portions of the HDP oxide layer 230 and portions of the nitride layer 228 may be removed from the semiconductor device 200. In some implementations, a planarization tool 110 may be used to perform a CMP operation or another type of planarization operation to remove portions of the HDP oxide layer 230. In some implementations, an etch tool 108 may be used to remove portions of the HDP oxide layer 230 and portions of the nitride layer 228 such that the sensing dielectric layer 226 (and the associated contact pedestal structures 234) is exposed over the sensing electrode 218. Other portions of the HDP oxide layer 230 and other portions of the nitride layer 228 may remain in the isolation trenches 224.

As shown in FIG. 4Q, the pressure port 246 may be formed on a portion of the sensing dielectric layer 226. A deposition tool 102 may be used to deposit the pressure port 246 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. Alternatively, a bonding tool 114 may be used to bond the pressure port 246 to the sensing dielectric layer 226.

As shown in FIG. 4R, the actuation membrane 240 may be bonded to the semiconductor device 200. In particular, the actuation membrane 240 may be bonded to the HDP oxide layer 230 and to the pressure port 246 of the semiconductor device 200. A bonding tool 114 may perform a dielectric-to-dielectric bonding operation to bond the dielectric coating 242 on the actuation membrane 240 to the HDP oxide layer 230 and to the pressure port 246 of the semiconductor device 200. Bonding of the actuation membrane 240 to the semiconductor device 200 results in formation of the cavity 244 between the actuation membrane 240 and the sensing dielectric layer 226. The dielectric coating 242 may be formed on the actuation membrane 240 prior to the dielectric-to-dielectric bonding operation. A deposition tool 102 may use a thermal oxide deposition technique (e.g., thermal oxidation) to deposit the dielectric coating 242.

As shown in FIG. 4S, a pressure relief port 404 may be formed in the actuation membrane 240 above the pressure port 246. In some implementations, a pattern in a photoresist layer is used to form the pressure relief port 404 through the actuation membrane 240. In these implementations, a deposition tool 102 is used to form the photoresist layer on the dielectric layer 248 on the actuation membrane 240. An exposure tool 104 is used to expose the photoresist layer to a radiation source to pattern the photoresist layer. A developer tool 106 is used to develop and removes portions of the photoresist layer to expose the pattern. An etch tool 108 is used to etch through the dielectric layer 248, through the actuation membrane 240, and through the dielectric coating 242 to the pressure port 246. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the pressure relief port 404 based on a pattern.

As shown in FIG. 4T, conductive contacts 254 are formed through the dielectric layer 248 and on the actuation membrane 240 such that the conductive contacts 254 are electrically coupled and/or physically coupled with the actuation membrane 240. A conductive contact 254 may be formed in a recess in the dielectric layer 248. In some implementations, a pattern in a photoresist layer is used to form the recess in the dielectric layer 248. In these implementations, a deposition tool 102 is used to form the photoresist layer on the dielectric layer 248. An exposure tool 104 is used to expose the photoresist layer to a radiation source to pattern the photoresist layer. A developer tool 106 is used to develop and removes portions of the photoresist layer to expose the pattern. An etch tool 108 is used to etch into the dielectric layer 248 based on the pattern to form the recess. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recess based on a pattern.

A deposition tool 102 and/or a plating tool 112 may be used to deposit the conductive contact 254 in the recess over and/or on the actuation membrane 240 in a CVD operation, a PVD operation, an ALD operation, an electroplating operation, another deposition operation described above in connection with FIG. 1, and/or another suitable deposition operation. In some implementations, a seed layer is first deposited, and the conductive contact 254 is deposited on the seed layer.

As shown in FIG. 4U, portions of the dielectric layer 248 are removed after formation of the conductive contacts 254. An etch tool 108 is used to etch the dielectric layer 248 to remove the portions of the dielectric layer 248. In some implementations, the etch operation includes a plasma etch technique, a wet chemical etch technique, and/or another type of etch technique.

As shown in FIG. 4V, the capping layer 250 and the passivation layer 252 may be formed over and/or on the semiconductor device 200. A deposition tool 102 may be used to deposit the capping layer 250 and the passivation layer 252 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type.

As indicated above, FIGS. 4A-4V are provided as an example. Other examples may differ from what is described with regard to FIGS. 4A-4V.

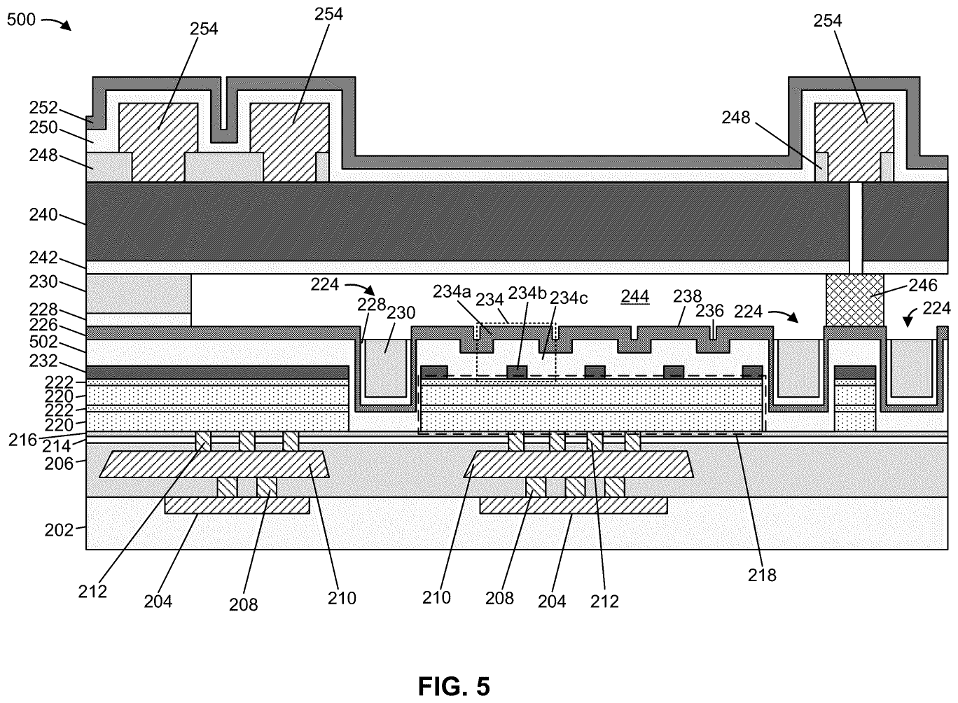

FIG. 5 is a diagram of an example semiconductor device 500 described herein. The semiconductor device 500 may be a MEMS device, such as an ultrasonic fingerprint sensor, among other examples. Additionally and/or alternatively, the semiconductor device 500 may include another type of MEMS device, such as an RF switch, a motion sensor, and/or another type of MEMS device having a mechanical contact and high operating voltage.

As shown in FIG. 5, the semiconductor device 500 may include a similar arrangement of elements 202-254 as the semiconductor device 200. However, the semiconductor device 500 includes an additional sensing dielectric layer 502 between the dielectric layer 232 and the sensing dielectric layer 226. The sensing dielectric layer 502 may also be included in the isolation trenches 224, as well as between the sensing dielectric layer 226 and the sensing electrode 218. Accordingly, the contact pedestal structures 234 may include a portion 234a of the sensing dielectric layer 226, a portion 234b of the dielectric layer 232, and a portion 234c of the sensing dielectric layer 502.

The sensing dielectric layer 502 may include a plasma enhanced oxide (PEOx), a plasma enhanced nitride, an aluminum oxide (AlₓO_{y}), and/or another dielectric material. In some implementations, the sensing dielectric layer 502 is deposited using a PECVD technique (e.g., for a PEOx, a plasma enhanced nitride such as a plasma enhanced silicon nitride (SiₓN_{y}), and/or a plasma enhanced silicon oxynitride (SiON)). In some implementations, the sensing dielectric layer 502 is deposited using an ALD technique (e.g., for aluminum oxide (AlₓO_{y})).

The combination of the sensing dielectric layer 226 and the sensing dielectric layer 502 may enable the dielectric constant of the CMUT of the semiconductor device 500 to be tuned or optimized while providing sufficient thickness to protect against breakdown voltage degradation in the CMUT. For example, the sensing dielectric layer 226 and the sensing dielectric layer 502 may be formed of different materials, such as an oxide-containing dielectric material for the sensing dielectric layer 226 and a nitride-containing dielectric material for the sensing dielectric layer 502 (e.g., a silicon nitride (SiN) and/or another nitride-containing dielectric material). The oxide-containing dielectric material may be formed of a low dielectric constant (low-k) dielectric material, whereas the nitride-containing dielectric material may be formed of a high dielectric constant (high-k) dielectric material. This enables different dielectric constant materials to be combined to achieve a desired overall dielectric constant for the CMUT.

A combination of the thicknesses of the sensing dielectric layer 226 and the sensing dielectric layer 502 is greater than the thickness of the dielectric coating 242. For example, the combination of the thicknesses of the sensing dielectric layer 226 and the sensing dielectric layer 502 may be included in a range of approximately 1,900 angstroms to approximately 4,000 angstroms. In some implementations, the thickness of the sensing dielectric layer 502 may be greater relative to a thickness of the sensing dielectric layer 226. In some implementations, the thickness of the sensing dielectric layer 226 may be greater relative to a thickness of the sensing dielectric layer 502.

In some implementations, the combination of the thicknesses of the sensing dielectric layer 226 and the sensing dielectric layer 502 is based on the maximum operating voltage (Vₘₐₓ), which may correspond to the maximum AC voltage or the maximum DC bias voltage of the CMUT. For example, the thickness of the sensing dielectric layer 226 may correspond to a value in a range of approximately

$$\frac{{V}_{max}}{1 , 000 V / μm}$$

to approximately

$$\frac{{V}_{max}}{500 V / μm} .$$

As an example, if Vₘₐₓ is 220 volts, the combination of the thicknesses of the sensing dielectric layer 226 and the sensing dielectric layer 502 may be included in a range of approximately 2,200 angstroms to approximately 4,400 angstroms. Selecting the value of the combination of the thicknesses of the sensing dielectric layer 226 and the sensing dielectric layer 502 from the range of approximately

$$\frac{{V}_{max}}{1 , 000 V / μm}$$

to approximately V

$$\frac{{V}_{max}}{500 V / μm}$$

enables a sufficiently high breakdown voltage to be maintained for the CMUT (e.g., even in the event of wear out of the dielectric coating 242) while enabling sufficient driving static force and sufficient capacitance to be achieved for the CMUT. Selecting the value of the combination of the thicknesses of the sensing dielectric layer 226 and the sensing dielectric layer 502 from outside of the range of approximately

$$\frac{{V}_{max}}{1 , 000 V / μm}$$

to approximately

$$\frac{{V}_{max}}{500 V / μm}$$

may result in too low of breakdown voltage, too low of driving static force, and/or too low of capacitance for the CMUT. However, other values and/or ranges other than approximately

$$\frac{{V}_{max}}{1 , 000 V / μm}$$

to approximately

$$\frac{{V}_{max}}{500 V / μm}$$

are within the scope of the present disclosure.

As indicated above, FIG. 5 is provided as an example. Other examples may differ from what is described with regard to FIG. 5.

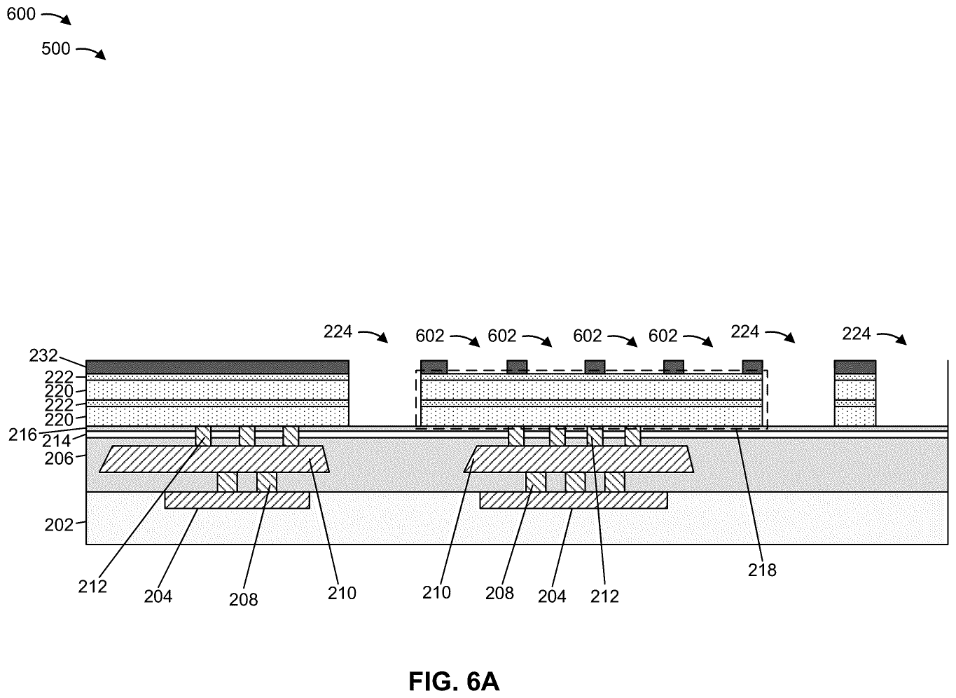

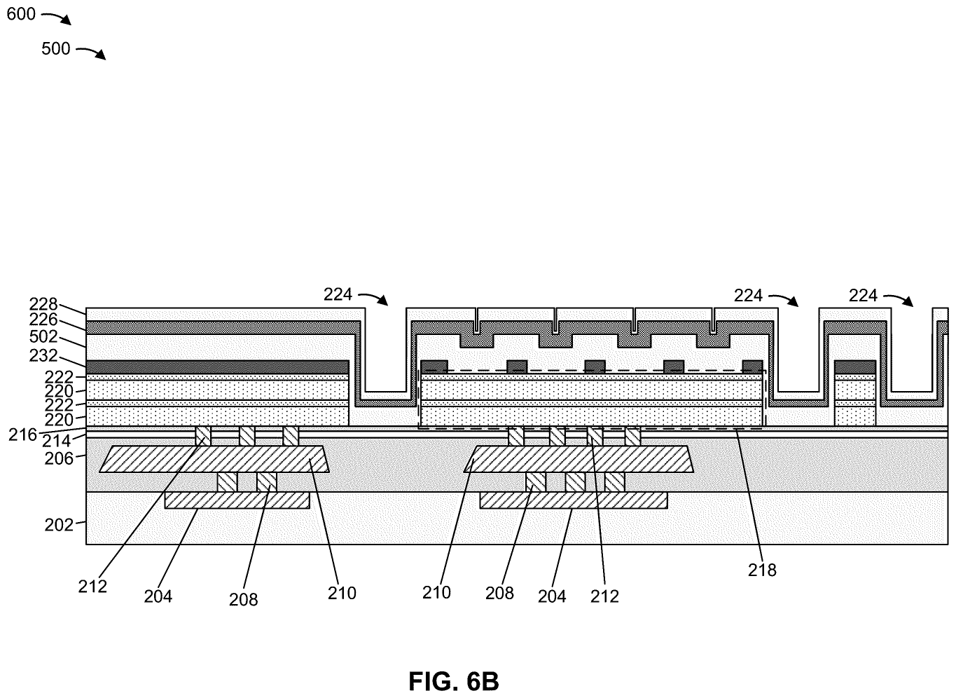

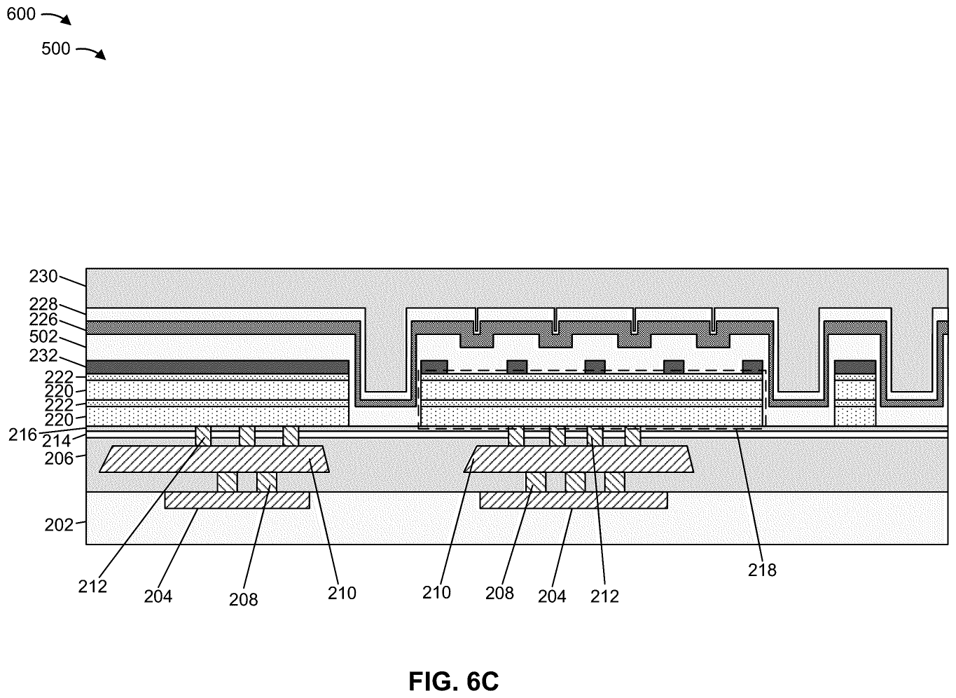

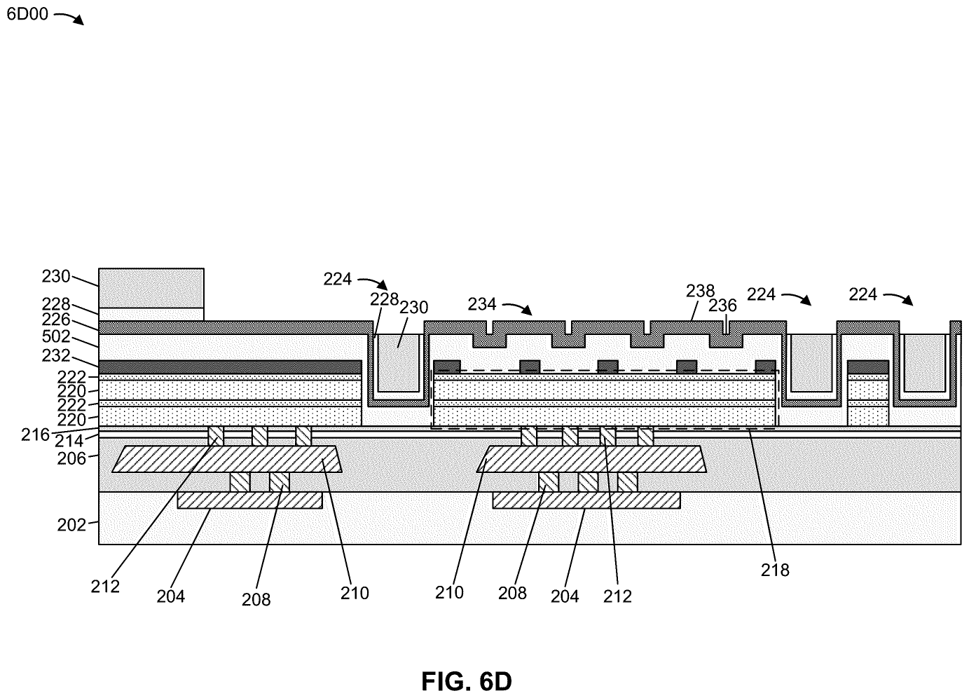

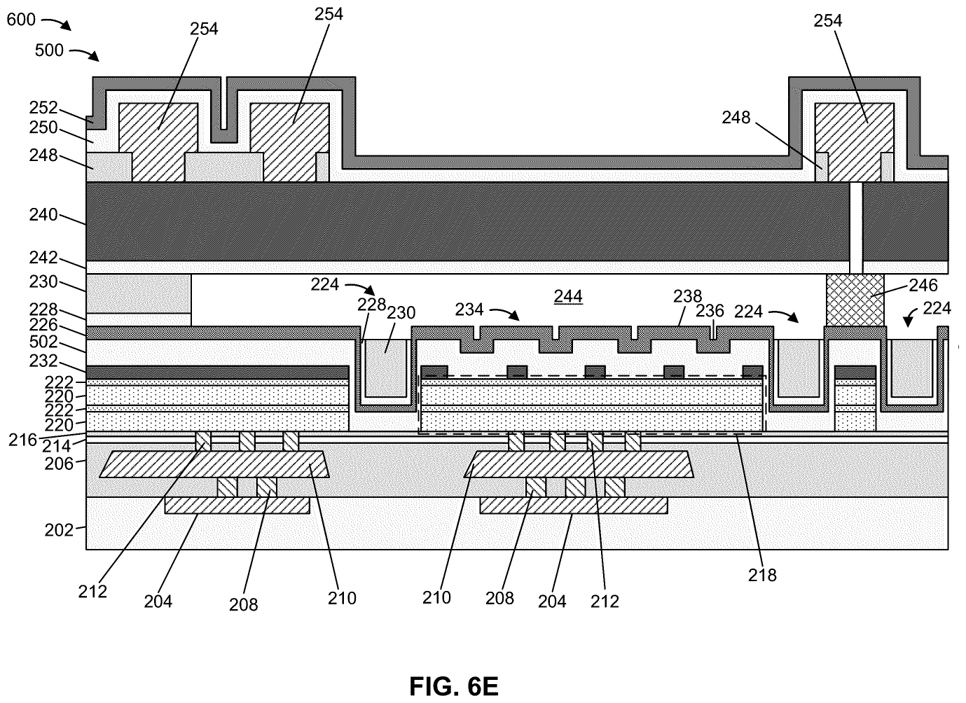

FIGS. 6A-6E are diagrams of an example implementation 600 of forming the semiconductor device 500 (or a portion thereof) described herein. In some implementations, one or more of the semiconductor processing operations described in connection with FIGS. 6A-6E may be performed using one or more of the semiconductor processing tools 102-114 described in connection with FIG. 1. In some implementations, one or more of the semiconductor processing operations described in connection with FIGS. 6A-6E may be performed using another semiconductor processing tool not shown in FIG. 1.

Turning to FIG. 6A, one or more semiconductor processing operations may be performed to form elements 202-224 and 232, and recesses 602 in the dielectric layer 232 above the sensing electrode 218, of the semiconductor device 500. Similar semiconductor processing operations to those described in connection with FIGS. 4A-4L may be used.

As shown in FIG. 6B, the sensing dielectric layer 502, the sensing dielectric layer 226, and the nitride layer 228 may be formed on the semiconductor device 500. The sensing dielectric layer 502 may be formed on the dielectric layer 232 and in the isolation trenches 224. The sensing dielectric layer 502 may also be formed on the sensing electrode 218. A portion 234c of the sensing dielectric layer 502 over the sensing electrode 218 covers portions 234b of the dielectric layer 232. The sensing dielectric layer 226 may be formed over and/or on the sensing dielectric layer 502. In particular, the sensing dielectric layer 226 may be formed over and/or on the sensing dielectric layer 502 in the isolation trenches 224 and over the sensing electrode 218. The nitride layer 228 may be formed over and/or on the sensing dielectric layer 226. In particular, the nitride layer 228 may be formed over and/or on the sensing dielectric layer 226 in the isolation trenches 224 and over the sensing electrode 218.

A deposition tool 102 may be used to deposit the sensing dielectric layer 502, the sensing dielectric layer 226, and the nitride layer 228 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, a deposition tool 102 is used to deposit the sensing dielectric layer 502 using a PECVD technique. The sensing dielectric layer 502 may be conformally deposited such that the sensing dielectric layer 502 conforms to the contours of the portions 234b of the dielectric layer 232. In some implementations, a deposition tool 102 is used to deposit the sensing dielectric layer 226 using a PECVD technique. The sensing dielectric layer 226 may be conformally deposited such that the sensing dielectric layer 226 conforms to the contours of the sensing dielectric layer 502. The nitride layer 228 may be conformally deposited such that the nitride layer 228 conforms to the contours of the sensing dielectric layer 226.

As shown in FIG. 6C, the HDP oxide layer 230 may be formed over and/or on the nitride layer 228. The HDP oxide layer 230 may be formed on the nitride layer 228 in the isolation trenches 224 and on the nitride layer 228 over the sensing electrode 218. A deposition tool 102 may be used to HDP oxide layer 230 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, the HDP oxide layer 230 is deposited using a high density plasma deposition technique to blanket deposit the HDP oxide layer 230.

As shown in FIG. 6D, portions of the HDP oxide layer 230 and portions of the nitride layer 228 may be removed from the semiconductor device 500. In some implementations, a planarization tool 110 may be used to perform a CMP operation or another type of planarization operation to remove portions of the HDP oxide layer 230. In some implementations, an etch tool 108 may be used to remove portions of the HDP oxide layer 230 and portions of the nitride layer 228 such that the sensing dielectric layer 226 (and the associated contact pedestal structures 234) is exposed over the sensing electrode 218. Other portions of the HDP oxide layer 230 and other portions of the nitride layer 228 may remain in the isolation trenches 224.

As shown in FIG. 6E, similar operations to those shown and described in connection with FIGS. 4Q-4V may subsequently be performed to form the remaining layers and/or structures of the CMUT of the semiconductor device 500.

As indicated above, FIGS. 6A-6E are provided as an example. Other examples may differ from what is described with regard to FIGS. 6A-6E.

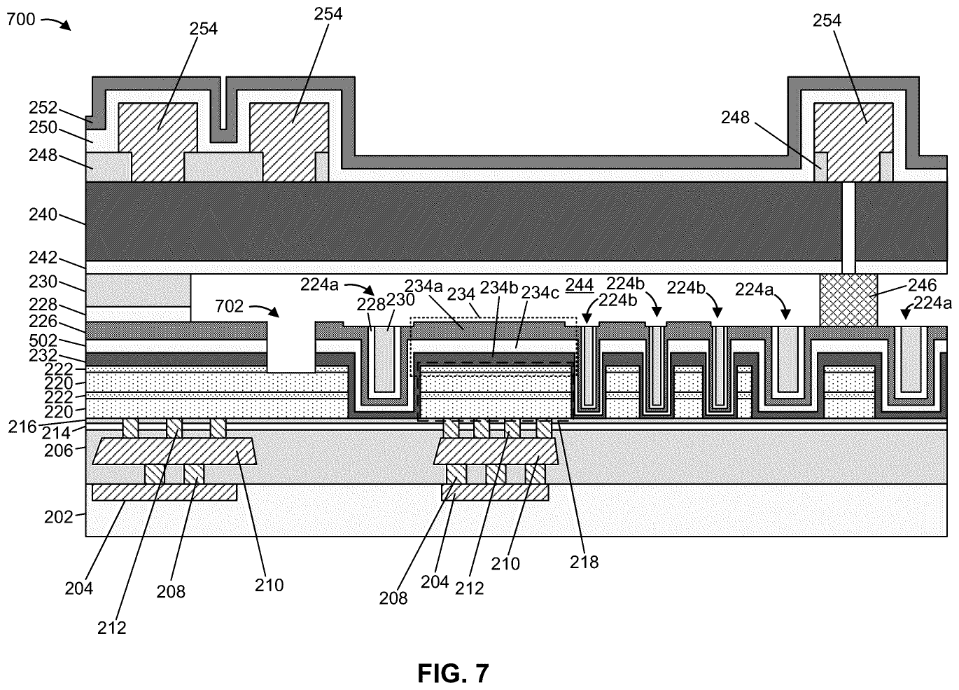

FIG. 7 is a diagram of an example semiconductor device 700 described herein. The semiconductor device 700 may be a MEMS device, such as an ultrasonic fingerprint sensor, among other examples. Additionally and/or alternatively, the semiconductor device 700 may include another type of MEMS device, such as an RF switch, a motion sensor, and/or another type of MEMS device having a mechanical contact and high operating voltage.

As shown in FIG. 7, the semiconductor device 700 may include a similar arrangement of elements 202-254 and 502 as the semiconductor device 500. As further shown in FIG. 7, the semiconductor device 700 may include a combination of isolation trenches 224a and floating electrode trenches 224b that extend through the stack of alternating metal layers 220 and metal nitride layer 222. The floating electrode trenches 224b may further segment or partition the sensing electrodes 218 in the semiconductor device 700. The floating electrode trenches 224b may enable the sensing electrodes 218 to be electrically floating (e.g., not connected to a grounding structure). This may further extend the lifetime of the CMUT of the semiconductor device 700 by reducing the electrical breakdown of the CMUT if one or more of the dielectric layers under the contact pedestal structures 234 become damaged.

As shown in FIG. 7, the width of the floating electrode trenches 224b may be less than the width of the isolation trenches 224a to enable a high density of sensing electrodes 218 to be included in the semiconductor device 700. The isolation trenches 224a and the floating electrode trenches 224b may each include a portion of the dielectric layer 232 (which is omitted from the isolation trenches 224 in the semiconductor device 200 and the semiconductor device 500), a portion of the sensing dielectric layer 502, a portion of the sensing dielectric layer 226, a portion of the nitride layer 228, and a portion of the HDP oxide layer 230, among other examples. The semiconductor device 700 may further include a buffer tank 702 that extends through the sensing dielectric layer 226, through the sensing dielectric layer 502, through the dielectric layer 232, and through the top metal nitride layer 222. The buffer tank 702 may be included to tune or optimize the pressure in the cavity 244.

As indicated above, FIG. 7 is provided as an example. Other examples may differ from what is described with regard to FIG. 7.

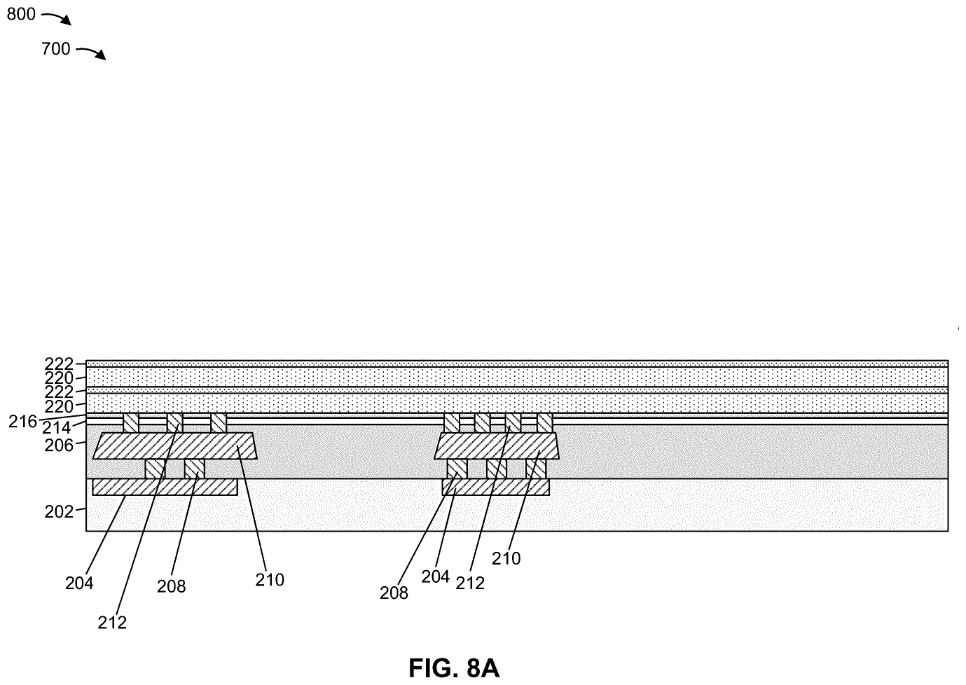

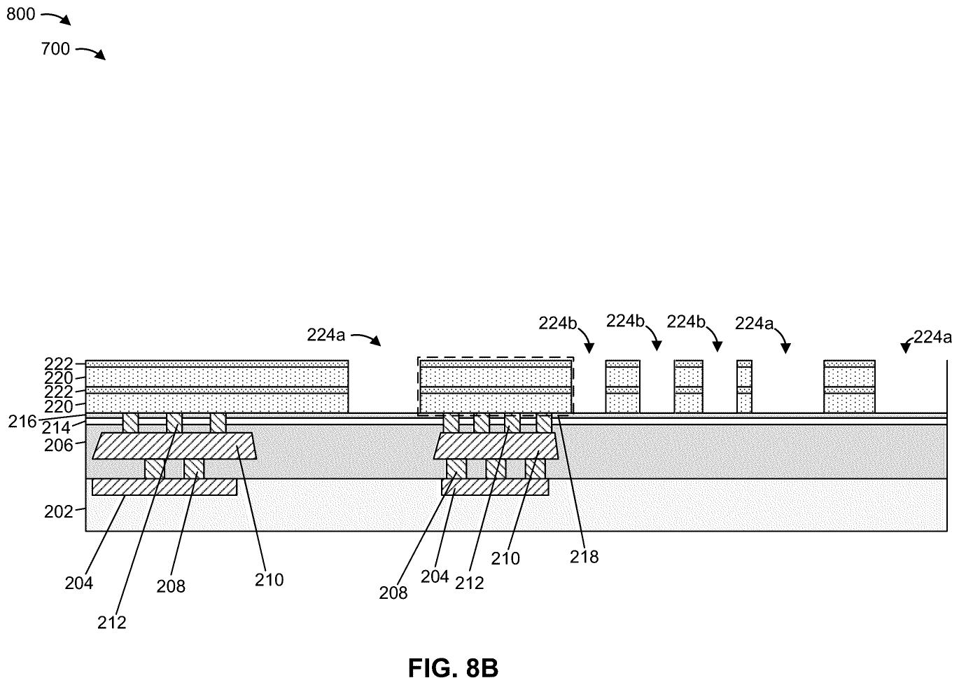

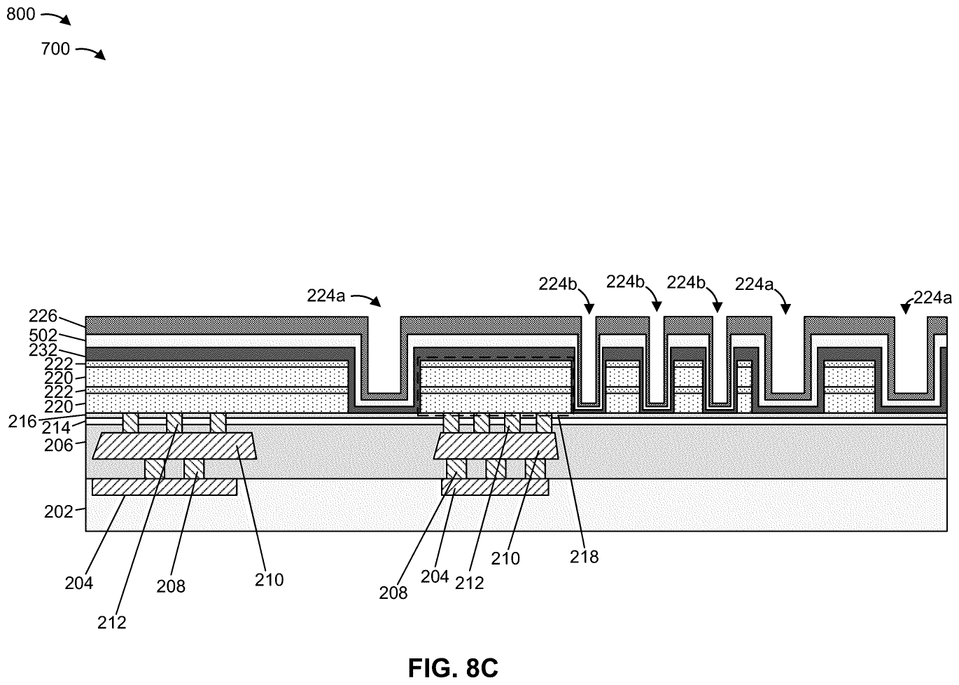

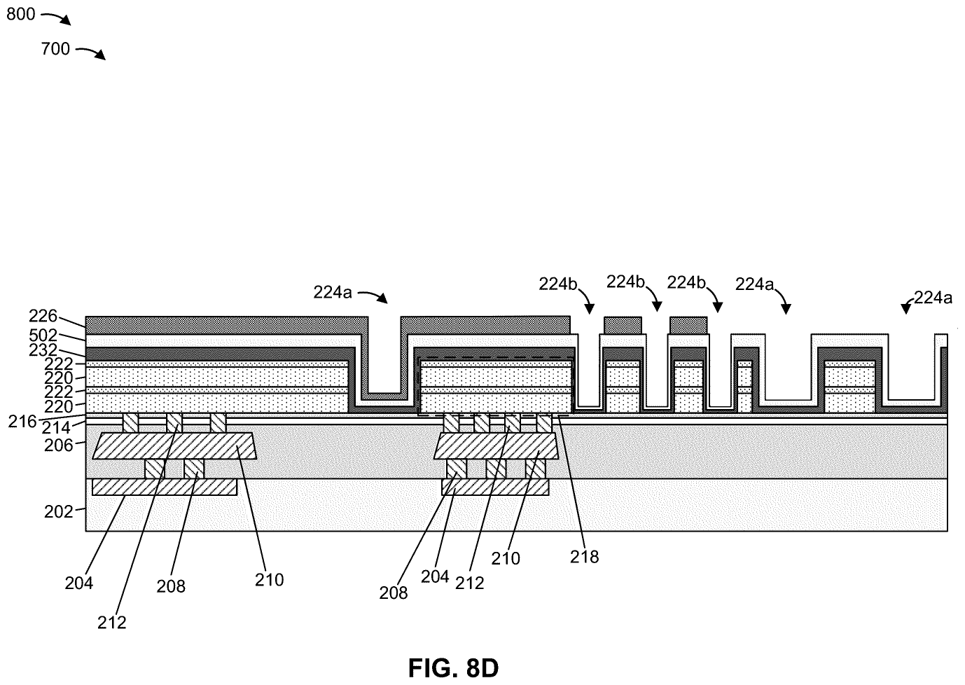

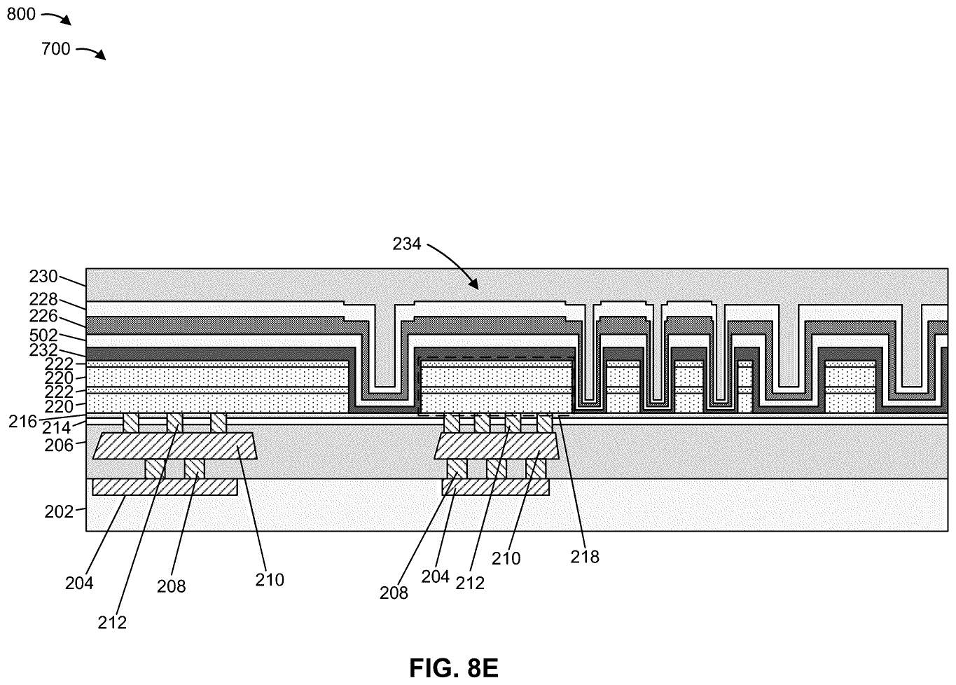

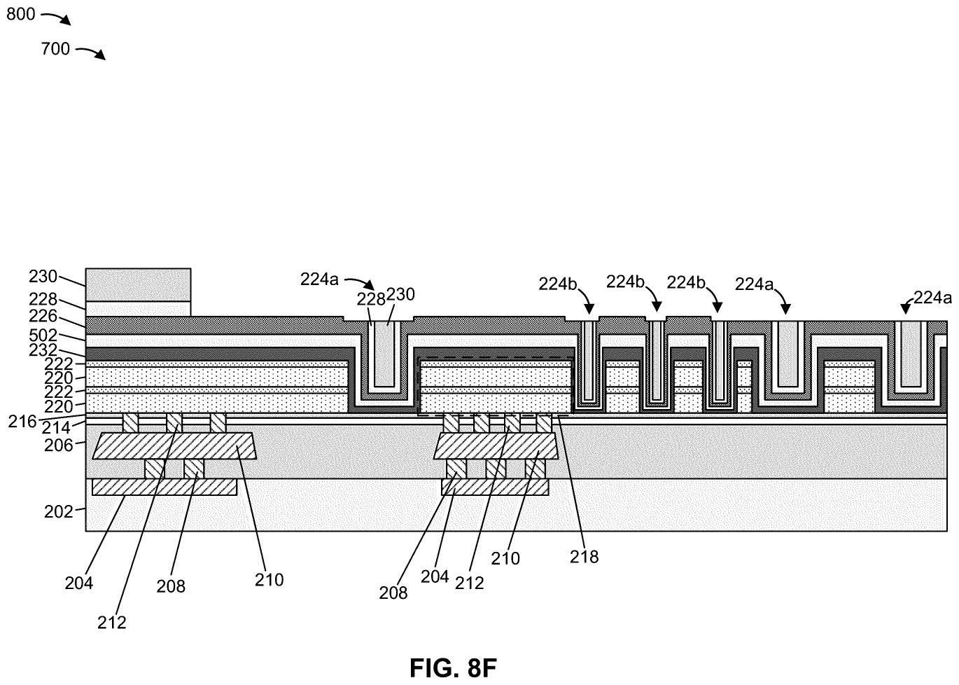

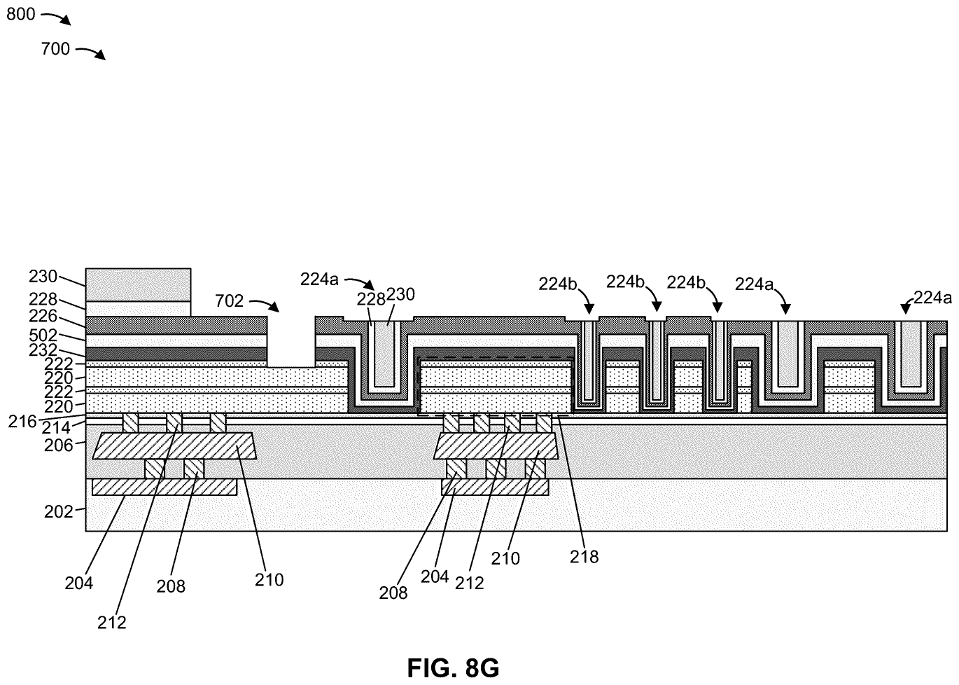

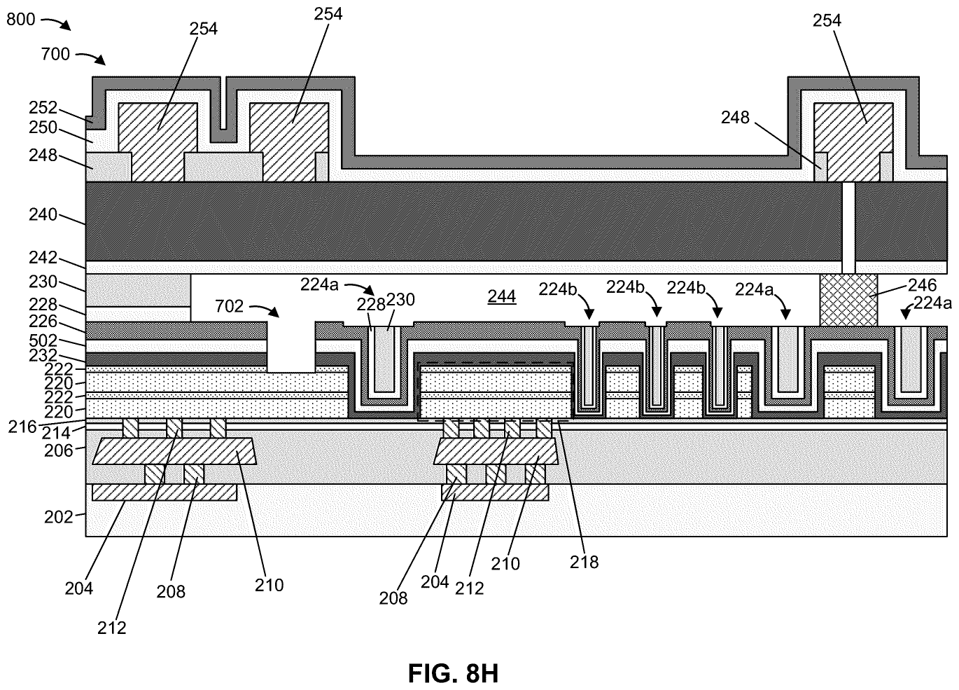

FIGS. 8A-8H are diagrams of an example implementation 800 of forming the semiconductor device 700 (or a portion thereof) described herein. In some implementations, one or more of the semiconductor processing operations described in connection with FIGS. 8A-8H may be performed using one or more of the semiconductor processing tools 102-114 described in connection with FIG. 1. In some implementations, one or more of the semiconductor processing operations described in connection with FIGS. 8A-8H may be performed using another semiconductor processing tool not shown in FIG. 1.

Turning to FIG. 8A, one or more semiconductor processing operations may be performed to form elements 202-224 of the semiconductor device 700. Similar semiconductor processing operations to those described in connection with FIGS. 4A-4I may be used.

As shown in FIG. 8B, isolation trenches 224a and the floating electrode trenches 224b may be formed through the alternating stack of metal layers 220 and metal nitride layer 222. Unlike the isolation trenches 224 formed in the semiconductor device 200 in FIG. 4L, the isolation trenches 224a and the floating electrode trenches 224b may be formed in the semiconductor device 700 prior to formation of the dielectric layer 232. This may be referred to as a “pedestal last” process. The formation of the isolation trenches 224a and the floating electrode trenches 224b results in formation of the sensing electrode 218 of the CMUT of the semiconductor device 700. The isolation trenches 224a may electrically isolate the sensing electrode 218, and the floating electrode trenches 224b may enable a ground connection for the sensing electrode 218 to be a floating ground connection.

In some implementations, a pattern in a photoresist layer is used to form the isolation trenches 224a and the floating electrode trenches 224b through the alternating stack of metal layers 220 and metal nitride layer 222. In these implementations, a deposition tool 102 is used to form the photoresist layer on the top metal nitride layer 222. An exposure tool 104 is used to expose the photoresist layer to a radiation source to pattern the photoresist layer. A developer tool 106 is used to develop and removes portions of the photoresist layer to expose the pattern. An etch tool 108 is used to etch through the alternating stack of metal layers 220 and metal nitride layer 222 based on the pattern to form the isolation trenches 224a and the floating electrode trenches 224b. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the isolation trenches 224a and the floating electrode trenches 224b based on a pattern.

As shown in FIG. 8C, the dielectric layer 232, the sensing dielectric layer 502, and the sensing dielectric layer 226 may be formed on the semiconductor device 700. The dielectric layer 232 may be formed on the top metal nitride layer 222 and in the isolation trenches 224a and the floating electrode trenches 224b. The dielectric layer 232 may also be formed on the sensing electrode 218. The sensing dielectric layer 502 may be formed over and/or on the dielectric layer 232. In particular, the sensing dielectric layer 502 may be formed over and/or on the dielectric layer 232 in the isolation trenches 224a and the floating electrode trenches 224b, and on the dielectric layer 232 over the sensing electrode 218. The sensing dielectric layer 226 may be formed over and/or on the sensing dielectric layer 502. In particular, the sensing dielectric layer 226 may be formed over and/or on the sensing dielectric layer 502 in the isolation trenches 224a and the floating electrode trenches 224b, and on the sensing dielectric layer 502 over the sensing electrode 218.

A deposition tool 102 may be used to deposit the dielectric layer 232, the sensing dielectric layer 502, and the sensing dielectric layer 226, in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, a deposition tool 102 is used to deposit the sensing dielectric layer 502 using a PECVD technique. The sensing dielectric layer 502 may be conformally deposited such that the sensing dielectric layer 502 conforms to the profile of the isolation trenches 224a and the floating electrode trenches 224b. In some implementations, a deposition tool 102 is used to deposit the sensing dielectric layer 226 using a PECVD technique. The sensing dielectric layer 226 may be conformally deposited such that the sensing dielectric layer 226 conforms to the profile of the isolation trenches 224a and the floating electrode trenches 224b.

As shown in FIG. 8D, portions of the sensing dielectric layer 226 may be removed to facilitate formation of the contact pedestal structures 234. For example, portions of the sensing dielectric layer 226 may be removed from one or more of the isolation trenches 224a, from one or more of the floating electrode trenches 224b, and/or from one or more portions of the sensing dielectric layer 502. In some implementations, a pattern in a photoresist layer is used to remove portions of the sensing dielectric layer 226. In these implementations, a deposition tool 102 is used to form the photoresist layer on the sensing dielectric layer 226. An exposure tool 104 is used to expose the photoresist layer to a radiation source to pattern the photoresist layer. A developer tool 106 is used to develop and removes portions of the photoresist layer to expose the pattern. An etch tool 108 is used to etch through the sensing dielectric layer 226 based on the pattern to remove portions of the sensing dielectric layer 226. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for remove portions of the sensing dielectric layer 226 based on a pattern.

As shown in FIG. 8E, additional material for the sensing dielectric layer 226 may be deposited. The additional material for the sensing dielectric layer 226 may be formed over the sensing dielectric layer 226 to create the contact pedestal structures 234. The additional material for the sensing dielectric layer 226 may also be deposited in the isolation trenches 224a and the floating electrode trenches 224b. In some implementations, a deposition tool 102 is used to deposit the additional material of the sensing dielectric layer 226 using a PECVD technique.

As further shown in FIG. 8E, the nitride layer 228 may be formed on the sensing dielectric layer 226. The nitride layer 228 may be formed on the sensing dielectric layer 226 in the isolation trenches 224a, on the sensing dielectric layer 226 in the floating electrode trenches 224b, and on the sensing dielectric layer 226 over the sensing electrode 218. A deposition tool 102 may be used to deposit the nitride layer 228 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. The nitride layer 228 may be conformally deposited such that the nitride layer 228 conforms to the contours of the sensing dielectric layer 226.

As further shown in FIG. 8E, the HDP oxide layer 230 may be formed over and/or on the nitride layer 228. The HDP oxide layer 230 may be formed on the nitride layer 228 in the isolation trenches 224a, on the nitride layer 228 in the floating electrode trenches 224b, and on the nitride layer 228 over the sensing electrode 218. A deposition tool 102 may be used to deposit the HDP oxide layer 230 in one or more PVD operations, one or more ALD operations, one or more CVD operations, one or more epitaxy operations, one or more oxidation operations, one or more deposition operations of another type described in connection with FIG. 1, and/or one or more deposition operations of another suitable type. In some implementations, the HDP oxide layer 230 is deposited using a high density plasma deposition technique to blanket deposit the HDP oxide layer 230.

As shown in FIG. 8F, portions of the HDP oxide layer 230 and portions of the nitride layer 228 may be removed from the semiconductor device 700. In some implementations, a planarization tool 110 may be used to perform a CMP operation or another type of planarization operation to remove portions of the HDP oxide layer 230. In some implementations, an etch tool 108 may be used to remove portions of the HDP oxide layer 230 and portions of the nitride layer 228 such that the sensing dielectric layer 226 (and the associated contact pedestal structures 234) is exposed over the sensing electrode 218. Other portions of the HDP oxide layer 230 and other portions of the nitride layer 228 may remain in the isolation trenches 224a and in the floating electrode trenches 224b.

As shown in FIG. 8G, the buffer tank 702 may be formed in and/or through the sensing dielectric layer 226, the sensing dielectric layer 502, the dielectric layer 232, and/or the top metal nitride layer 222. In some implementations, a pattern in a photoresist layer is used to form the buffer tank 702. In these implementations, a deposition tool 102 is used to form the photoresist layer on the sensing dielectric layer 226. An exposure tool 104 is used to expose the photoresist layer to a radiation source to pattern the photoresist layer. A developer tool 106 is used to develop and removes portions of the photoresist layer to expose the pattern. An etch tool 108 is used to etch into the sensing dielectric layer 226, the sensing dielectric layer 502, the dielectric layer 232, and/or the top metal nitride layer 222 based on the pattern to form the buffer tank 702. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the buffer tank 702 based on a pattern.

As shown in FIG. 8H, similar operations to those shown and described in connection with FIGS. 4Q-4V may subsequently be performed to form the remaining layers and/or structures of the CMUT of the semiconductor device 700.

As indicated above, FIGS. 8A-8H are provided as an example. Other examples may differ from what is described with regard to FIGS. 8A-8H.

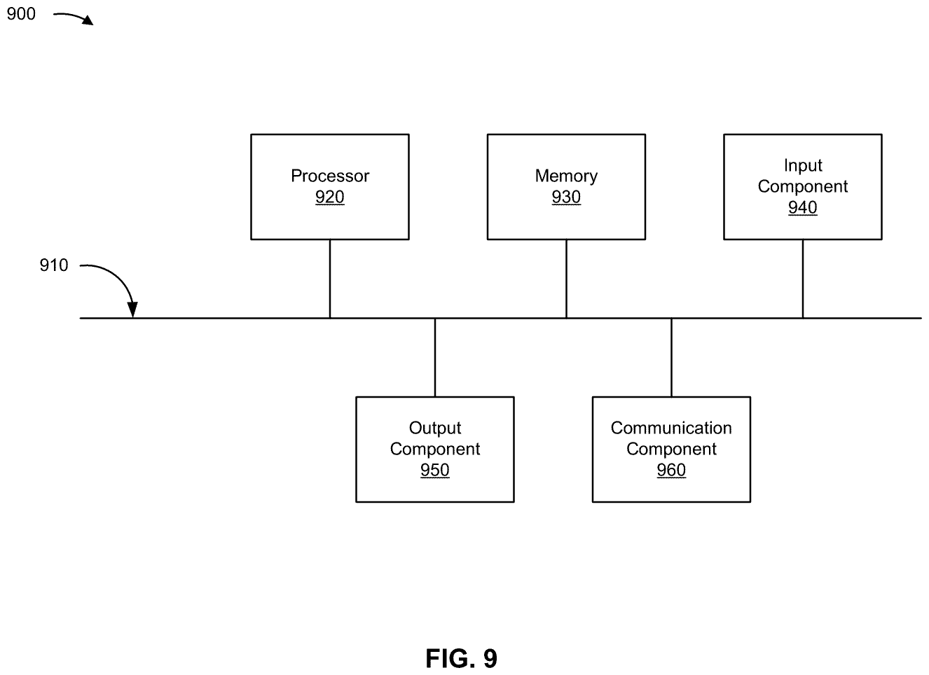

FIG. 9 is a diagram of example components of a device 900 described herein. In some implementations, one or more of the semiconductor processing tools 102-114 and/or the wafer/die transport tool 116 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

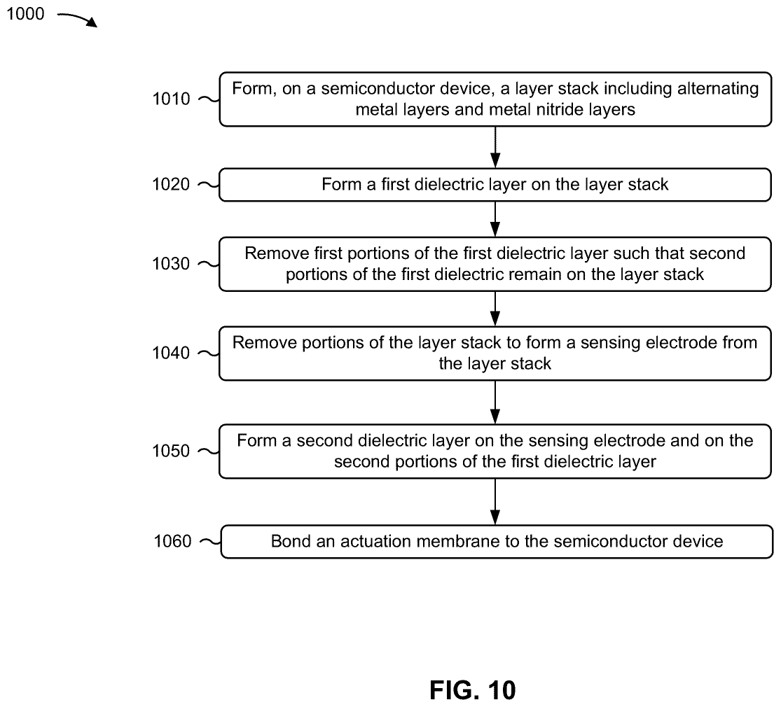

FIG. 10 is a flowchart of an example process 1000 associated with forming a semiconductor device described herein. In some implementations, one or more process blocks of FIG. 10 are performed using one or more semiconductor processing tools (e.g., one or more of the semiconductor processing tools 102-114). Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include forming, on a semiconductor device, a layer stack including alternating metal layers and metal nitride layers (block 1010). For example, one or more of the semiconductor processing tools 102-114 may be used to form, on a semiconductor device 200, a layer stack including alternating metal layers 220 and metal nitride layers 222, as described herein.

As further shown in FIG. 10, process 1000 may include forming a first dielectric layer on the layer stack (block 1020). For example, one or more of the semiconductor processing tools 102-114 may be used to form the first dielectric layer (e.g., the dielectric layer 232) on the layer stack, as described herein.

As further shown in FIG. 10, process 1000 may include removing first portions of the first dielectric layer such that second portions of the first dielectric layer remain on the layer stack (block 1030). For example, one or more of the semiconductor processing tools 102-114 may be used to remove first portions of the first dielectric layer such that second portions (e.g., portions 234b) of the first dielectric layer remain on the layer stack, as described herein.

As further shown in FIG. 10, process 1000 may include removing portions of the layer stack to form a sensing electrode from the layer stack (block 1040). For example, one or more of the semiconductor processing tools 102-114 may be used to remove portions of the layer stack to form a sensing electrode 218 from the layer stack, as described herein. In some implementations, the second portions of the first dielectric layer are included on the sensing electrode 218. In some implementations, removing portions of the layer stack results in formation of isolation trenches 224 on opposing sides of the sensing electrode 218.

As further shown in FIG. 10, process 1000 may include forming a second dielectric layer on the sensing electrode and on the second portions of the first dielectric layer (block 1050). For example, one or more of the semiconductor processing tools 102-114 may be used to form a second dielectric layer (e.g., a sensing dielectric layer 226) on the sensing electrode and on the second portions of the first dielectric layer, as described herein. In some implementations, the second dielectric layer is formed in the isolation trenches 224. In some implementations, forming the second dielectric layer on the second portions of the first dielectric layer results in formation of a plurality of contact pedestal structures 234 over the sensing electrode 218. In some implementations, a nitride layer 228 and an HDP oxide layer 230 may be formed over the second dielectric layer in the isolation trenches 224. In some implementations, a pressure port 246 may be formed over the second dielectric layer adjacent to the sensing electrode 218. In some implementations, forming the second dielectric layer includes performing a PECVD technique to deposit a plasma enhanced oxide material for the second dielectric layer.

As further shown in FIG. 10, process 1000 may include bonding an actuation membrane to the semiconductor device (block 1060). For example, one or more of the semiconductor processing tools 102-112 may be used to bond an actuation membrane 240 to the semiconductor device 200, as described herein. In some implementations, bonding the actuation membrane 240 to the semiconductor device 200 results in formation of a cavity 244 between the actuation membrane 240 and the second dielectric layer. In some implementations, a dielectric coating 242 is formed on the actuation membrane 240 prior to bonding the actuation membrane 240 to the semiconductor device 200. In some implementations, the dielectric coating 242 is facing the cavity 244. In some implementations, the dielectric coating 242 is formed using a thermal oxidation technique. In some implementations, a thickness of the second dielectric layer is greater than a thickness of the dielectric coating 242.

Process 1000 may include additional implementations, such as any single implementation or any combination of implementations described below and/or in connection with one or more other processes described elsewhere herein.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

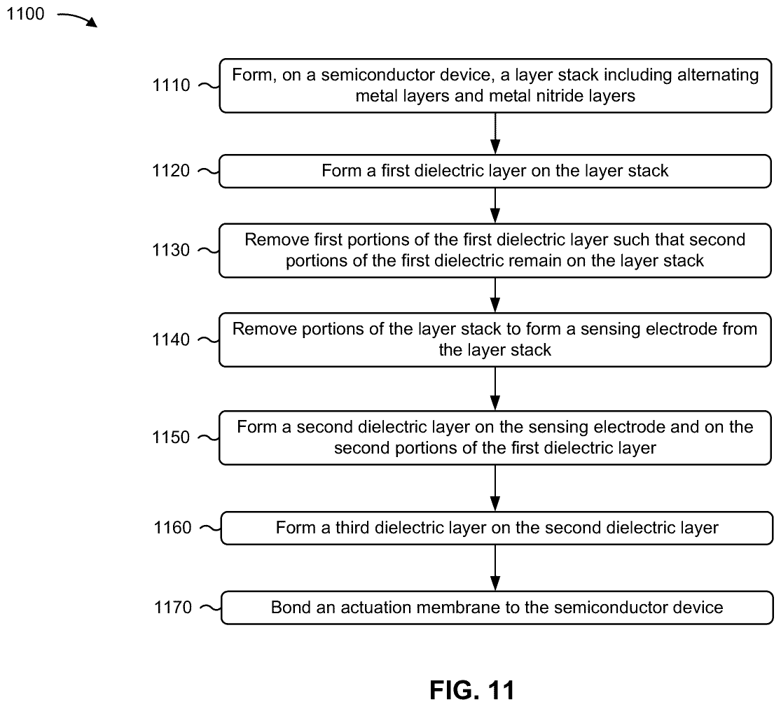

FIG. 11 is a flowchart of an example process 1100 associated with forming a semiconductor device described herein. In some implementations, one or more process blocks of FIG. 11 are performed using one or more semiconductor processing tools (e.g., one or more of the semiconductor processing tools 102-114). Additionally, or alternatively, one or more process blocks of FIG. 11 may be performed by one or more components of device 900, such as processor 920, memory 930, input component 940, output component 950, and/or communication component 960.

As shown in FIG. 11, process 1100 may include forming, on a semiconductor device, a layer stack including alternating metal layers and metal nitride layers (block 1110). For example, one or more of the semiconductor processing tools 102-114 may be used to form, on a semiconductor device 500, a layer stack including alternating metal layers 220 and metal nitride layers 222, as described herein.

As further shown in FIG. 11, process 1100 may include forming a first dielectric layer on the layer stack (block 1120). For example, one or more of the semiconductor processing tools 102-114 may be used to form the first dielectric layer (e.g., the dielectric layer 232) on the layer stack, as described herein.

As further shown in FIG. 11, process 1100 may include removing first portions of the first dielectric layer such that second portions of the first dielectric layer remain on the layer stack (block 1130). For example, one or more of the semiconductor processing tools 102-114 may be used to remove first portions of the first dielectric layer such that second portions (e.g., portions 234b) of the first dielectric layer remain on the layer stack, as described herein.

As further shown in FIG. 11, process 1100 may include removing portions of the layer stack to form a sensing electrode from the layer stack (block 1140). For example, one or more of the semiconductor processing tools 102-114 may be used to remove portions of the layer stack to form a sensing electrode 218 from the layer stack, as described herein. In some implementations, the second portions of the first dielectric layer are included on the sensing electrode 218. In some implementations, removing portions of the layer stack results in formation of isolation trenches 224 on opposing sides of the sensing electrode 218.

As further shown in FIG. 11, process 1100 may include forming a second dielectric layer on the sensing electrode and on the second portions of the first dielectric layer (block 1150). For example, one or more of the semiconductor processing tools 102-114 may be used to form a second dielectric layer (e.g., a sensing dielectric layer 502) on the sensing electrode and on the second portions of the first dielectric layer, as described herein. In some implementations, the second dielectric layer is formed in the isolation trenches 224. In some implementations, forming the second dielectric layer on the second portions of the first dielectric layer results in formation of a plurality of contact pedestal structures 234 over the sensing electrode 218. In some implementations, a nitride layer 228 and an HDP oxide layer 230 may be formed over the second dielectric layer in the isolation trenches 224. In some implementations, a pressure port 246 may be formed over the second dielectric layer adjacent to the sensing electrode 218. In some implementations, forming the second dielectric layer includes performing a PECVD technique to deposit a plasma enhanced oxide material for the second dielectric layer.

As further shown in FIG. 11, process 1100 may include forming a third dielectric layer on the second dielectric layer (block 1160). For example, one or more of the semiconductor processing tools 102-114 may be used to form a third dielectric layer (e.g., a sensing dielectric layer 226) on the second dielectric layer, as described herein. In some implementations, the third dielectric layer is formed in the isolation trenches 224. In some implementations, forming the third dielectric layer on the second portions of the second dielectric layer results in formation of a plurality of contact pedestal structures 234 over the sensing electrode 218. In some implementations, a nitride layer 228 and an HDP oxide layer 230 may be formed over the third dielectric layer in the isolation trenches 224. In some implementations, a pressure port 246 may be formed over the third dielectric layer adjacent to the sensing electrode 218. In some implementations, forming the third dielectric layer includes performing a PECVD technique to deposit a plasma enhanced nitride material for the third dielectric layer. In some implementations, the second dielectric layer and the third dielectric layer include different dielectric materials. In some implementations, the first dielectric layer and the third dielectric layer include a same combination of dielectric materials.

As further shown in FIG. 11, process 1100 may include bonding an actuation membrane to the semiconductor device (block 1170). For example, one or more of the semiconductor processing tools 102-112 may be used to bond an actuation membrane 240 to the semiconductor device 500, as described herein. In some implementations, bonding the actuation membrane 240 to the semiconductor device 500 results in formation of a cavity 244 between the actuation membrane 240 and the third dielectric layer. In some implementations, a dielectric coating 242 is formed on the actuation membrane 240 prior to bonding the actuation membrane 240 to the semiconductor device 500. In some implementations, the dielectric coating 242 is facing the cavity 244. In some implementations, the dielectric coating 242 is formed using a thermal oxidation technique. In some implementations, a combined thickness of the second dielectric layer and the third dielectric layer is greater than a thickness of the dielectric coating 242.

Process 1100 may include additional implementations, such as any single implementation or any combination of implementations described below and/or in connection with one or more other processes described elsewhere herein.

Although FIG. 11 shows example blocks of process 1100, in some implementations, process 1100 includes additional blocks, fewer blocks, different blocks, or differently arranged blocks than those depicted in FIG. 10. Additionally, or alternatively, two or more of the blocks of process 1100 may be performed in parallel.

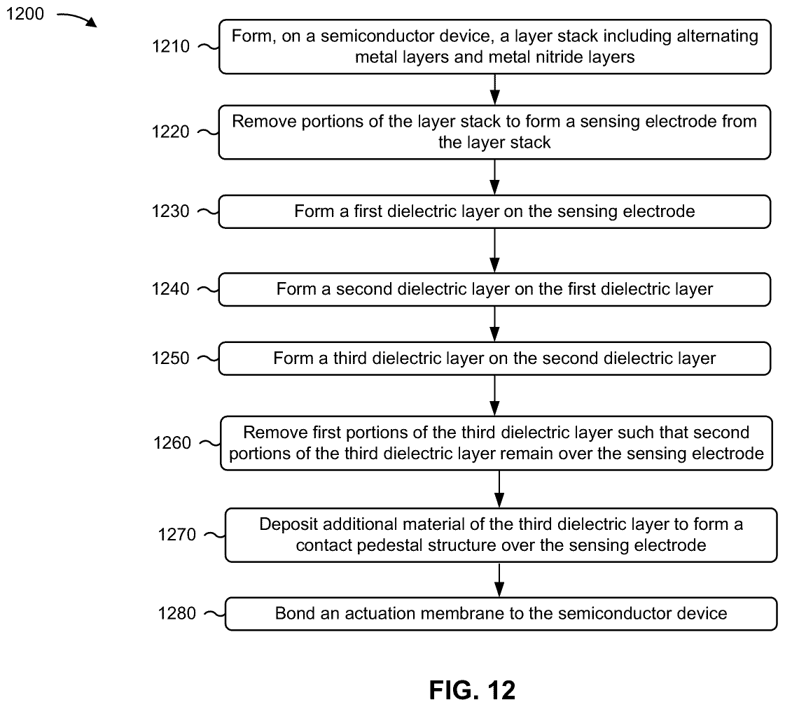

FIG. 12 is a flowchart of an example process 1200 associated with forming a semiconductor device described herein. In some implementations, one or more process blocks of FIG. 12 are performed using one or more semiconductor processing tools (e.g., one or more of the semiconductor processing tools 102-114). Additionally, or alternatively, one or more process blocks of FIG. 12 may be performed by one or more components of device 900, such as processor 920, memory 930, input component 940, output component 950, and/or communication component 960.

As shown in FIG. 12, process 1200 may include forming, on a semiconductor device, a layer stack including alternating metal layers and metal nitride layers (block 1210). For example, one or more of the semiconductor processing tools 102-114 may be used to form, on a semiconductor device 700, a layer stack including alternating metal layers 220 and metal nitride layers 222, as described herein.

As further shown in FIG. 12, process 1200 may include removing portions of the layer stack to form a sensing electrode from the layer stack (block 1220). For example, one or more of the semiconductor processing tools 102-114 may be used to remove portions of the layer stack to form a sensing electrode 218 from the layer stack, as described herein. In some implementations, removing portions of the layer stack results in formation of isolation trenches 224a on opposing sides of the sensing electrode 218. In some implementations, removing portions of the layer stack results in formation of one or more floating electrode trenches 224b between an isolation trench 224a and the sensing electrode 218.

As further shown in FIG. 12, process 1200 may include forming a first dielectric layer on the sensing electrode (block 1230). For example, one or more of the semiconductor processing tools 102-114 may be used to form the first dielectric layer (e.g., the dielectric layer 232) on the sensing electrode 218, as described herein. In some implementations, the first dielectric layer is formed in the isolation trenches 224a. In some implementations, the first dielectric layer is formed in the floating electrode trenches 224b.

As further shown in FIG. 12, process 1200 may include forming a second dielectric layer on the first dielectric layer (block 1240). For example, one or more of the semiconductor processing tools 102-114 may be used to form the second dielectric layer (e.g., the sensing dielectric layer 502) on the first dielectric layer, as described herein. In some implementations, the second dielectric layer is formed over and/or on the first dielectric layer in the isolation trenches 224a. In some implementations, the second dielectric layer is formed over and/or on the first dielectric layer in the floating electrode trenches 224b. In some implementations, the second dielectric layer is formed over and/or on the first dielectric layer over the sensing electrode 218.

As further shown in FIG. 12, process 1200 may include forming a third dielectric layer on the second dielectric layer (block 1250). For example, one or more of the semiconductor processing tools 102-114 may be used to form the third dielectric layer (e.g., the sensing dielectric layer 226) on the second dielectric layer, as described herein. In some implementations, the third dielectric layer is formed over and/or on the second dielectric layer in the isolation trenches 224a. In some implementations, the third dielectric layer is formed over and/or on the second dielectric layer in the floating electrode trenches 224b. In some implementations, the third dielectric layer is formed over and/or on the second dielectric layer over the sensing electrode 218.

As further shown in FIG. 12, process 1200 may include removing first portions of the third dielectric layer such that second portions of the third dielectric layer remain over the sensing electrode (block 1260). For example, one or more of the semiconductor processing tools 102-114 may be used to remove first portions of the third dielectric layer such that second portions (e.g., portions 234a) of the third dielectric layer remain over the sensing electrode 218, as described herein. In some implementations, the first portions may be removed as part of forming a contact pedestal structure 234 over the sensing electrode 218.

As further shown in FIG. 12, process 1200 may include depositing additional material of the third dielectric layer to form a contact pedestal structure over the sensing electrode (block 1270). For example, one or more of the semiconductor processing tools 102-114 may be used to deposit additional material of the third dielectric layer to form a contact pedestal structure 234 over the sensing electrode 218, as described herein. In some implementations, the additional material may be deposited in one or more of the isolation trenches 224a. In some implementations, the additional material may be deposited in one or more of the floating electrode trenches 224b.

As further shown in FIG. 12, process 1200 may include bonding an actuation membrane to the semiconductor device (block 1280). For example, one or more of the semiconductor processing tools 102-112 may be used to bond an actuation membrane 240 to the semiconductor device 700, as described herein. In some implementations, bonding the actuation membrane 240 to the semiconductor device 700 results in formation of a cavity 244 between the actuation membrane 240 and the third dielectric layer. In some implementations, a dielectric coating 242 is formed on the actuation membrane 240 prior to bonding the actuation membrane 240 to the semiconductor device 700. In some implementations, the dielectric coating 242 is facing the cavity 244. In some implementations, the dielectric coating 242 is formed using a thermal oxidation technique. In some implementations, a combined thickness of the second dielectric layer and the third dielectric layer is greater than a thickness of the dielectric coating 242.

Process 1200 may include additional implementations, such as any single implementation or any combination of implementations described below and/or in connection with one or more other processes described elsewhere herein.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

In this way, a MEMS device may include a CMUT that includes an actuation membrane and a sensing dielectric layer that are spaced apart by a cavity (e.g., an airgap). The sensing dielectric layer may be formed such that the thickness of the sensing dielectric layer may extend the operational of the CMUT while enabling the CMUT to accommodate a sufficiently high V_{dc-bias} for collapsed mode operation. For example, the thickness of the sensing dielectric layer may be greater than a thickness of the dielectric coating on the underside of the actuation membrane. In this way, the thickness of the sensing dielectric layer enables the CMUT to operate in the collapsed mode, which enables the CMUT to achieve greater sound pressure output relative to other operational modes and enables the frequency response of the CMUT to be adjustable, thereby enabling the frequency response to be optimized for specific use cases and applications. Moreover, the thickness of the sensing dielectric layer may enable the CMUT to operate at a sustained high breakdown voltage over a longer period of time (e.g., relative to CMUTs that include a thinner sensing dielectric layer), which reduces the likelihood of premature wear out and extends the operational life of the CMUT.

As described in greater detail above, some implementations described herein provide a semiconductor device. The semiconductor device includes a sensing electrode above a substrate and between a plurality of isolation trenches. The semiconductor device includes a plurality of portions of a first dielectric layer on the sensing electrode. The semiconductor device includes a portion of a second dielectric layer on the sensing electrode and on the plurality of portions of the first dielectric layer. The semiconductor device includes an actuation membrane above the second dielectric layer, where the actuation membrane and the second dielectric layer are spaced apart by a cavity. The semiconductor device includes a third dielectric layer on the actuation membrane, where the third dielectric layer is between the actuation membrane and the cavity, and where a thickness of the portion of the second dielectric layer is greater than a thickness of the third dielectric layer.

As described in greater detail above, some implementations described herein provide a semiconductor device. The semiconductor device includes a sensing electrode above a substrate and between a plurality of isolation trenches. The semiconductor device includes a plurality of portions of a first dielectric layer on the sensing electrode. The semiconductor device includes a portion of a second dielectric layer on the sensing electrode and on the plurality of portions of the first dielectric layer. The semiconductor device includes a portion of a third dielectric layer on the portion of the second dielectric layer. The semiconductor device includes an actuation membrane above the third dielectric layer, where the actuation membrane and the third dielectric layer are spaced apart by a cavity.

As described in greater detail above, some implementations described herein provide a semiconductor device. The semiconductor device includes a sensing electrode above a substrate and between a first isolation trench and a second isolation trench. The semiconductor device includes a contact pedestal structure on the sensing electrode and between the first isolation trench and a floating electrode trench, the contact pedestal structure comprising, a portion of a first dielectric layer on the sensing electrode a portion of a second dielectric layer on the sensing electrode and on the portion of the first dielectric layer a portion of a third dielectric layer on the portion of the second dielectric layer. The semiconductor device includes an actuation membrane above the third dielectric layer, where the actuation membrane and the contact pedestal structure are spaced apart by a cavity.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a sensing electrode above a substrate and between a plurality of isolation trenches;
a plurality of portions of a first dielectric layer on the sensing electrode;
a portion of a second dielectric layer on the sensing electrode and on the plurality of portions of the first dielectric layer,
an actuation membrane above the second dielectric layer,
wherein the actuation membrane and the second dielectric layer are spaced apart by a cavity; and
a third dielectric layer on the actuation membrane,
wherein the third dielectric layer is between the actuation membrane and the cavity, and
wherein a thickness of the portion of the second dielectric layer is greater than a thickness of the third dielectric layer.

2. The semiconductor device of claim 1, wherein the plurality of portions of the first dielectric layer and the portion of the second dielectric layer form a plurality of contact pedestal structures over the sensing electrode.

3. The semiconductor device of claim 2, wherein the sensing electrode, the actuation membrane, and the plurality of contact pedestal structures correspond to a capacitive micromachined ultrasonic transducer (CMUT) included in the semiconductor device.

4. The semiconductor device of claim 1, wherein the first dielectric layer comprises at least one of:
a plasma enhanced oxide,
a plasma enhanced nitride, or
an aluminum oxide (AlₓO_{y}).

5. The semiconductor device of claim 4, wherein the second dielectric layer comprises at least one of:
a plasma enhanced oxide,
a plasma enhanced nitride, or
a aluminum oxide (AlₓO_{y}).

6. The semiconductor device of claim 5, wherein the third dielectric layer comprises a thermal oxide.

7. A semiconductor device, comprising:
a sensing electrode above a substrate and between a plurality of isolation trenches;
a plurality of portions of a first dielectric layer on the sensing electrode;
a portion of a second dielectric layer on the sensing electrode and on the plurality of portions of the first dielectric layer;
a portion of a third dielectric layer on the portion of the second dielectric layer; and
an actuation membrane above the third dielectric layer,
wherein the actuation membrane and the third dielectric layer are spaced apart by a cavity.

8. The semiconductor device of claim 7, wherein a thickness of the second dielectric layer is greater than a thickness of the first dielectric layer; and
wherein the thickness of the second dielectric layer is greater than a thickness of the third dielectric layer.

9. The semiconductor device of claim 7, wherein the second dielectric layer, the third dielectric layer, a fourth dielectric layer, and a fifth dielectric layer are included in the plurality of isolation trenches.

10. The semiconductor device of claim 7, wherein the first dielectric layer comprises a plasma enhanced oxide.

11. The semiconductor device of claim 10, wherein the second dielectric layer comprises a plasma enhanced nitride.

12. The semiconductor device of claim 11, wherein the third dielectric layer comprises another plasma enhanced oxide.

13. The semiconductor device of claim 7, wherein the plurality of portions of the first dielectric layer, the portion of the second dielectric layer, and the portion of the third dielectric layer form a plurality of contact pedestal structures over the sensing electrode.

14. The semiconductor device of claim 13, wherein the sensing electrode, the actuation membrane, and the plurality of contact pedestal structures correspond to a capacitive micromachined ultrasonic transducer (CMUT) included in the semiconductor device.

15. A method, comprising:
forming, on a semiconductor device, a layer stack including alternating metal layers and metal nitride layers;
removing portions of the layer stack to form a sensing electrode from the layer stack;
forming a first dielectric layer on the sensing electrode;
forming a second dielectric layer on the first dielectric layer;
forming a third dielectric layer on the second dielectric layer;
remove first portions of the third dielectric layer such that second portions of the third dielectric layer remain over the sensing electrode;
deposit additional material of the third dielectric layer to form a contact pedestal structure over the sensing electrode; and
bond an actuation membrane to the semiconductor device.

16. The method of claim 15, wherein the first dielectric layer, the second dielectric layer, the third dielectric layer, a fourth dielectric layer, and a fifth dielectric layer are included in an isolation trench.

17. The method of claim 15, wherein the first dielectric layer, the second dielectric layer, the third dielectric layer, a fourth dielectric layer, and a fifth dielectric layer are included in a floating electrode trench.

18. The method of claim 16, wherein the first dielectric layer comprises a plasma enhanced oxide;
wherein the second dielectric layer comprises a plasma enhanced nitride;
wherein the third dielectric layer comprises another plasma enhanced oxide.

19. The method of claim 17, wherein the fourth dielectric layer comprises another plasma enhanced nitride; and
wherein the fifth dielectric layer comprises a high-density plasma oxide.

20. The method of claim 15, wherein the sensing electrode, the actuation membrane, and the contact pedestal structure correspond to a capacitive micromachined ultrasonic transducer (CMUT) included in the semiconductor device.
